(19) United States
(12) Patent Application Publication
(10) Pub. No.: US 2026/0025898 A1
(43) Pub. Date: Jan. 22, 2026

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventors: Shogo KITASAKA, Oyama-shi (JP); Yoshifumi UENO, Oyama-shi (JP); Atsushi UEDA, Oyama-shi (JP)

(73) Assignee: Gigaphoton Inc., Tochigi (JP)

(21) Appl. No.: 19/231,207

(22) Filed: Jun. 6, 2025

(30) Foreign Application Priority Data
Jul. 16, 2024 (JP) 2024-113651

(51) Int. Cl. H05G 2/00; G03F 7/00

(52) U.S. Cl. CPC H05G 2/0084; H05G 2/0027; H05G 2/0094; G03F 7/70033

(57) ABSTRACT

An extreme ultraviolet light generation apparatus includes a chamber in which a target substance supplied to a plasma generation region is irradiated with laser light to generate extreme ultraviolet light, a laser device generating the laser light, a target supply unit supplying a droplet of the target substance toward the plasma generation region, a target collection unit collecting the target substance which has not been irradiated with the laser light, a first gas supply unit supplying a buffer gas into the chamber, and a processor controlling the first gas supply unit so that, in a period of the droplet being output, a first flow rate of the buffer gas to be supplied from the first gas supply unit in at least a part of a first period is smaller than a second flow rate of the buffer gas to be supplied from the first gas supply unit in a second period.

### CROSS-REFERENCE TO RELATED APPLICATIONS

The present application claims the benefit of Japanese Patent Application No. 2024-113651, filed on Jul. 16, 2024, the entire contents of which are hereby incorporated by reference.

### BACKGROUND

### 1. Technical Field

The present disclosure relates to an extreme ultraviolet light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the extreme ultraviolet light generation apparatus, a laser produced plasma (LPP) type apparatus using plasma generated by irradiating a target substance with laser light has been developed.

### LIST OF DOCUMENTS

### Patent Documents

Patent Document 1: U.S. Pat. No. 10,225,917
Patent Document 2: U.S. Pat. No. 11,092,896
Patent Document 3: U.S. Pat. No. 9,661,730

### SUMMARY

An extreme ultraviolet light generation apparatus according to an aspect of the present disclosure includes a chamber in which a target substance supplied to a plasma generation region at an internal space thereof is irradiated with laser light to generate extreme ultraviolet light, a laser device configured to generate the laser light, a target supply unit configured to supply a droplet of the target substance toward the plasma generation region, a target collection unit arranged on a trajectory of the output target substance and configured to collect the target substance which has not been irradiated with the laser light, a first gas supply unit configured to supply a buffer gas into the chamber, and a processor. Here, the processor is configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.

An electronic device manufacturing method according to an aspect of the present disclosure includes outputting extreme ultraviolet light generated using an extreme ultraviolet light generation apparatus to an exposure apparatus, and exposing a photosensitive substrate to the extreme ultraviolet light in the exposure apparatus to manufacture an electronic device. Here, the extreme ultraviolet light generation apparatus includes a chamber in which a target substance supplied to a plasma generation region at an internal space thereof is irradiated with laser light to generate the extreme ultraviolet light, a laser device configured to generate the laser light, a target supply unit configured to output a droplet of the target substance toward the plasma generation region, a target collection unit arranged on a trajectory of the output target substance and configured to collect the target substance which has not been irradiated with the laser light, a first gas supply unit configured to supply a buffer gas into the chamber, and a processor. The processor is configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.

An electronic device manufacturing method according to another aspect of the present disclosure includes inspecting a defect of a mask by irradiating the mask with extreme ultraviolet light generated using an extreme ultraviolet light generation apparatus, selecting a mask using a result of the inspection, and exposing and transferring a pattern formed on the selected mask onto a photosensitive substrate. Here, the extreme ultraviolet light generation apparatus includes a chamber in which a target substance supplied to a plasma generation region at an internal space thereof is irradiated with laser light to generate the extreme ultraviolet light, a laser device configured to generate the laser light, a target supply unit configured to output a droplet of the target substance toward the plasma generation region, a target collection unit arranged on a trajectory of the output target substance and configured to collect the target substance which has not been irradiated with the laser light, a first gas supply unit configured to supply a buffer gas into the chamber, and a processor. The processor is configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire electronic device manufacturing apparatus different from the electronic device manufacturing apparatus shown in FIG. 1.

FIG. 3 is a schematic view showing a schematic configuration example of an entire extreme ultraviolet light generation system of a comparative example.

FIG. 4 is a schematic view showing an extreme ultraviolet light generation apparatus in a cross section perpendicular to a trajectory of a droplet in the comparative example.

FIG. 5 is a schematic view showing the extreme ultraviolet light generation apparatus in a cross section along the trajectory of the droplet in the comparative example.

FIG. 6 is a flowchart showing operation flow of the extreme ultraviolet light generation system of the comparative example.

FIG. 7A is a chart showing transition of the gas pressure in a space at which the target supply unit is arranged in each step of FIG. 6. FIG. 7B is a chart showing transition of a gas supply amount in each step of FIG. 6.

FIG. 7C is a chart showing transition in temperature and pressure of the target supply unit in each step of FIG. 6.

FIG. 7D is a chart showing transition in duty of a piezoelectric element of the target supply unit in each step of FIG. 6. FIG. 7E is a chart showing transition of a determination result of droplet interval in each step of FIG. 6. FIG. 7F is a chart showing transition of a determination result of stability of extreme ultraviolet light in each step of FIG. 6.

FIG. 8 is a partially enlarged view of FIG. 4.

FIG. 9 is a schematic view viewed from an opening side in FIG. 5.

FIG. 10 is a schematic view showing a case in which a droplet having a small diameter is output in FIG. 5.

FIG. 11 is a flowchart showing operation flow of the extreme ultraviolet light generation system of a first embodiment.

FIG. 12A is a chart showing transition of the gas pressure in the space at which the target supply unit is arranged in each step of FIG. 11. FIG. 12B is a chart showing transition of the gas supply amount in each step of FIG. 11. FIG. 12C is a chart showing transition in temperature and pressure of the target supply unit in each step of FIG. 11. FIG. 12D is a chart showing transition in duty of a piezoelectric element of the target supply unit in each step of FIG. 11. FIG. 12E is a chart showing transition of the determination result of droplet interval in each step of FIG. 11. FIG. 12F is a chart showing transition of the determination result of stability of extreme ultraviolet light in each step of FIG. 11.

FIG. 13 is a schematic view showing a case in which the droplet having a small diameter is output in the first embodiment.

FIG. 14 is a flowchart showing operation flow of the extreme ultraviolet light generation system of a first modification of the first embodiment.

FIG. 15 is a flowchart showing operation flow of the extreme ultraviolet light generation system of a second modification of the first embodiment.

FIG. 16 is a flowchart showing operation flow of the extreme ultraviolet light generation system of a second embodiment.

FIG. 17A is a chart showing transition of the gas pressure in the space at which the target supply unit is arranged in each step of FIG. 16. FIG. 17B is a chart showing transition of the gas supply amount in each step of FIG. 16. FIG. 17C is a chart showing transition in temperature and pressure of the target supply unit in each step of FIG. 16. FIG. 17D is a chart showing transition in duty of a piezoelectric element of the target supply unit in each step of FIG. 16. FIG. 17E is a chart showing transition of the determination result of droplet interval in each step of FIG. 16. FIG. 17F is a chart showing transition of the determination result of stability of extreme ultraviolet light in each step of FIG. 16.

FIG. 18 is a flowchart showing operation flow of the extreme ultraviolet light generation system of a first modification of the second embodiment.

FIG. 19A is a chart showing transition of the gas pressure in the space at which the target supply unit is arranged in each step of FIG. 18. FIG. 19B is a chart showing transition of the gas supply amount in each step of FIG. 18.

FIG. 20 is a schematic view showing the extreme ultraviolet light generation apparatus in a cross section along the trajectory of the droplet in a second modification of the second embodiment.

FIG. 21 is a flowchart showing operation flow of the extreme ultraviolet light generation system of the second modification of the second embodiment.

FIG. 22A is a chart showing transition of the gas pressure in the space at which the target supply unit is arranged in each step of FIG. 21. FIG. 22B is a chart showing transition of the gas supply amount in each step of FIG. 21.

FIG. 23 is a flowchart showing operation flow of the extreme ultraviolet light generation system of a third embodiment.

FIG. 24A is a chart showing transition of the gas pressure in the space at which the target supply unit is arranged in each step of FIG. 23. FIG. 24B is a chart showing transition of the gas supply amount in each step of FIG. 23. FIG. 24C is a chart showing transition of a gas exhaust amount in each step of FIG. 23.

### DESCRIPTION OF EMBODIMENTS

1. Overview
2. Description of electronic device manufacturing apparatus
3. Description of extreme ultraviolet light generation apparatus of comparative example
   3.1 Configuration
   3.2 Operation
   3.3 Problem
4. Description of extreme ultraviolet light generation apparatus of first embodiment
   4.1 Configuration
   4.2 Operation
   4.3 Effect
   4.4 First modification
      4.4.1 Configuration
      4.4.2 Operation
      4.4.3 Effect
   4.5 Second modification
      4.5.1 Configuration
      4.5.2 Operation
      4.5.3 Effect
5. Description of extreme ultraviolet light generation apparatus of second embodiment
   5.1 Configuration
   5.2 Operation
   5.3 Effect
   5.4 First modification
      5.4.1 Configuration
      5.4.2 Operation
      5.4.3 Effect
   5.5 Second modification
      5.5.1 Configuration
      5.5.2 Operation
      5.5.3 Effect
6. Description of extreme ultraviolet light generation apparatus of third embodiment
   6.1 Configuration
   6.2 Operation
   6.3 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overview

Embodiments of the present disclosure relate to an extreme ultraviolet light generation apparatus generating light having a wavelength of extreme ultraviolet (EUV) and an electronic device manufacturing apparatus. In the following, extreme ultraviolet light is referred to as EUV light in some cases.

### 2. Description of Electronic Device Manufacturing Apparatus

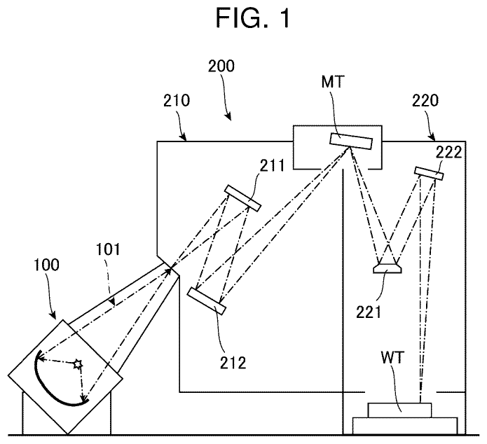

FIG. 1 is a schematic view showing a schematic configuration example of an entire electronic device manufacturing apparatus. The electronic device manufacturing apparatus shown in FIG. 1 includes an extreme ultraviolet light generation apparatus 100, and an exposure apparatus 200. The exposure apparatus 200 includes a mask irradiation unit 210 including a plurality of mirrors 211, 212 that configure a reflection optical system, and a workpiece irradiation unit 220 including a plurality of mirrors 221, 222 that configure a reflection optical system different from the reflection optical system of the mask irradiation unit 210. The mask irradiation unit 210 illuminates, via the mirrors 211, 212, a mask pattern of a mask table MT with EUV light 101 entering from the extreme ultraviolet light generation apparatus 100. The workpiece irradiation unit 220 images the EUV light 101 reflected by the mask table MT onto a workpiece (not shown) placed on a workpiece table WT via the mirrors 221, 222. The workpiece is a photosensitive substrate such as a semiconductor wafer on which photoresist is applied. The exposure apparatus 200 synchronously translates the mask table MT and the workpiece table WT to expose the workpiece to the EUV light 101 reflecting the mask pattern. Through the exposure process as described above, a device pattern is transferred onto the semiconductor wafer, thereby a semiconductor device can be manufactured.

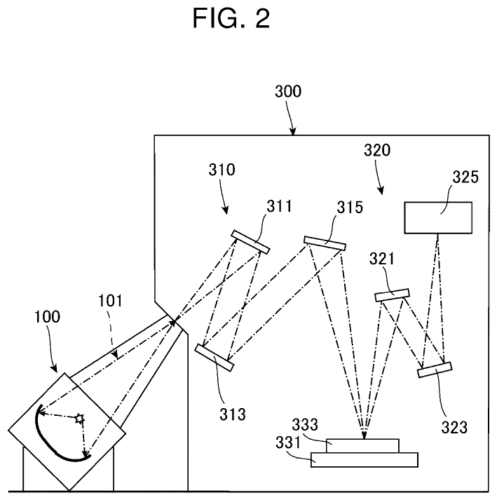

FIG. 2 is a schematic view showing a schematic configuration example of an entire electronic device manufacturing apparatus different from the electronic device manufacturing apparatus shown in FIG. 1. The electronic device manufacturing apparatus shown in FIG. 2 includes an extreme ultraviolet light generation apparatus 100 and an inspection apparatus 300. The inspection apparatus 300 includes an illumination optical system 310 including a plurality of mirrors 311, 313, 315 that configure a reflection optical system, and a detection optical system 320 including a detector 325 and a plurality of mirrors 321, 322 that configure a reflection optical system different from the reflection optical system of the illumination optical system 310. The illumination optical system 310 reflects, with the mirrors 311, 313, 315, the EUV light 101 entering from the extreme ultraviolet light generation apparatus 100 to illuminate a mask 333 placed on a mask stage 331. The mask 333 includes a mask blanks before a pattern is formed. The detection optical system 320 reflects, with the mirrors 321, 323, the EUV light 101 reflecting the pattern from the mask 333 and forms an image on a light receiving surface of the detector 325. The detector 325 having received the EUV light 101 acquires an image of the mask 333. The detector 325 is, for example, a time delay integration (TDI) camera. Inspection for a defect of the mask 333 is performed based on the image of the mask 333 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 200.

### 3. Description of Extreme Ultraviolet Light Generation Apparatus of Comparative Example

### 3.1 Configuration

The extreme ultraviolet light generation apparatus 100 of a comparative example will be described. The comparative example of the present disclosure is an example recognized by the applicant as known only by the applicant, and is not a publicly known example admitted by the applicant. Further, the following description will be given with reference to the extreme ultraviolet light generation apparatus 100 that outputs the EUV light 101 to the exposure apparatus 200 as a subsequent process apparatus as shown in FIG. 1. Here, the extreme ultraviolet light generation apparatus 100 that outputs the EUV light 101 to the inspection apparatus 300 as a subsequent process apparatus as shown in FIG. 2 can obtain the same operation and effect.

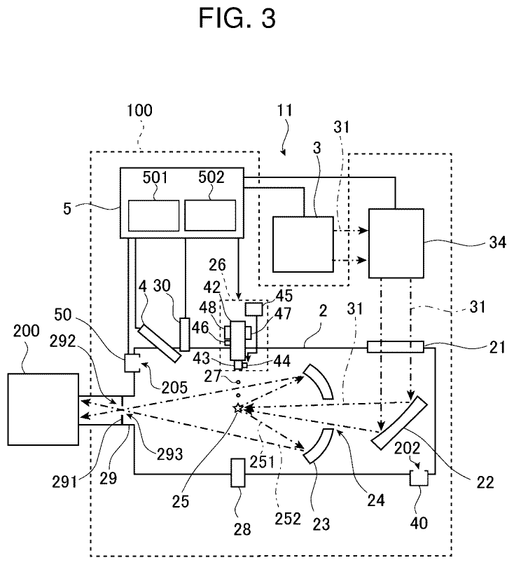

FIG. 3 schematically shows the configuration of an LPP extreme ultraviolet light generation system 11. The extreme ultraviolet light generation apparatus 100 is optically connected to a laser device 3. In the present disclosure, a system including the laser device 3 and the extreme ultraviolet light generation apparatus 100 is referred to as the extreme ultraviolet light generation system 11.

The laser device 3 includes a master oscillator being a light source to perform burst operation. The master oscillator outputs the pulse laser light 31 in a burst-on duration. The master oscillator is, for example, a solid-state laser device that excites a YAG crystal to which niobium (Nb) or ytterbium (Yb) is added, or a laser device that outputs the pulse laser light 31 by exciting a gas in which helium, nitrogen, or the like is mixed in a carbon dioxide gas through electric discharge. Alternatively, the master oscillator may be a quantum cascade laser device. The master oscillator may output the pulse laser light 31 by a Q switch system. Further, the master oscillator may include an optical switch, a polarizer, and the like. The laser device 3 may include an amplifier that amplifies the pulse laser light 31 output from the master oscillator. The burst operation is operation of repeatedly performing burst-on in which pulse laser light 31 is output at a predetermined repetition frequency and burst-off in which output of the pulse laser light 31 is stopped.

The extreme ultraviolet light generation apparatus 100 includes a chamber 2 that is a sealable container, a laser light transmission device 34 that transmits, to the chamber 2, the pulse laser light 31 output from the laser device 3, and a processor 5 that controls the extreme ultraviolet light generation system 11 as a main configuration.

The laser light transmission device 34 includes an optical element (not shown) for defining a transmission state of the pulse laser light 31, and an actuator (not shown) for adjusting the position, posture, and the like of the optical element. The pulse laser light 31 output from the laser device 3 is guided to the chamber 2 by the laser light transmission device 34. The chamber 2 includes a window 21, and the pulse laser light 31 enters the internal space of the chamber 2 through the window 21. A laser light concentrating mirror 22 is arranged at the internal space of the chamber 2, and the pulse laser light 31 is reflected and concentrated by the laser light concentrating mirror 22. The position of the laser light concentrating mirror 22 is adjusted so that a concentration position of the pulse laser light 31 at the internal space of the chamber 2 coincides with a position specified by the processor 5. The concentration position is adjusted to be a position directly below a nozzle 43 described later, and when a target substance is irradiated with the pulse laser light 31 at the concentration position, plasma is generated from the target substance, and radiation light 251 is radiated from the plasma. The radiation light 251 includes EUV light 252. The region in which plasma is generated is referred to as a plasma generation region 25. The plasma generation region 25 is a region having a radius of, for example, 40 mm about a plasma point and is located at the internal space of the chamber 2.

For example, an EUV light concentrating mirror 23 having a spheroidal reflection surface is arranged at the internal space of the chamber 2. The EUV light concentrating mirror 23 includes, for example, a multilayer film in which silicon layers and molybdenum layers are alternately laminated, and reflects EUV light 252 selectively from the radiation light 251 by the multilayer film. A through hole 24 is formed at the center of the EUV light concentrating mirror 23, and the pulse laser light 31 passes through the through hole 24. The EUV light concentrating mirror 23 has a first focal point and a second focal point. For example, the first focal point is located in the plasma generation region 25, and the second focal point is located at an intermediate focal point 292.

The extreme ultraviolet light generation apparatus 100 includes a connection portion 29 providing communication between the internal space of the chamber 2 and the internal space of the exposure apparatus 200. A wall 291 in which an aperture 293 is formed is arranged in the connection portion 29. The wall 291 is preferably arranged such that the aperture 293 is located at the second focal point. The connection portion 29 is an outlet port of the EUV light 252 in the chamber 2, and the EUV light 252 is output from the connection portion 29 and enters the exposure apparatus 200.

The target supply unit 26 is attached so as to penetrate a wall of the chamber 2. The target supply unit 26 includes a tank 42 and a pressure regulator 48, and supplies a droplet 27 to the internal space of the chamber 2 from a nozzle 43 attached to the tank 42.

The tank 42 stores therein the target substance which becomes the droplet 27. In the present comparative example, the target substance is tin. The material of the target substance may include tin, terbium, gadolinium, lithium, xenon, or a combination of any two or more thereof. The inside of the tank 42 is in communication with the pressure regulator 48 which adjusts the pressure in the tank 42. A heater 47 and a temperature sensor 46 are attached to the tank 42. The heater 47 heats the tank 42 with a current applied from a heater power source (not shown). Through the heating, the target substance in the tank 42 melts. The temperature sensor 46 measures, via the tank 42, the temperature of the target substance in the tank 42. The pressure regulator 48, the temperature sensor 46, and the heater power source are electrically connected to the processor 5.

The nozzle 43 is attached to the tank 42 and outputs the target substance. A piezoelectric element 44 is attached to the nozzle 43. The piezoelectric element 44 is electrically connected to a piezoelectric element power source 45, and is vibrated by a voltage applied from the piezoelectric element power source 45. The piezoelectric element power source 45 is electrically connected to the processor 5.

The chamber 2 includes a target collection unit 28. The target collection unit 28 is a box body attached to the chamber 2, and an opening thereof is arranged on a trajectory on which the target substance is output. The target collection unit 28 is a drain tank to collect any unnecessary droplet 27 having passed through the opening and reaching the target collection unit 28.

A gas supply unit 40 is connected to the chamber 2. A buffer gas contains a hydrogen gas, and the buffer gas of the present example is a hydrogen gas having a hydrogen concentration of 100% in effect. A gas flow rate adjustment unit (not shown) being a valve may be provided at the gas supply unit 40. For example, when the gas flow rate adjustment unit is provided, the processor 5 controls the gas flow rate adjustment unit to adjust the flow rate of the buffer gas to be supplied. Here, the buffer gas may be a balance gas having a hydrogen gas concentration of about 3%. In this case, the balance gas includes, for example, a nitrogen (Ne) gas or an argon (Ar) gas.

Further, the extreme ultraviolet light generation apparatus 100 includes a pressure sensor 30 and a target sensor 4. The pressure sensor 30 and the target sensor 4 are attached to the chamber 2 and are electrically connected to the processor 5. The pressure sensor 30 measures the pressure at the internal space of the chamber 2 and outputs a signal indicating the pressure to the processor 5.

The target sensor 4 has, for example, an imaging function, and detects the presence, interval, trajectory, position, velocity, and the like of the droplet 27 output from a nozzle hole of the nozzle 43 in accordance with an instruction from the processor 5. The target sensor 4 may be arranged inside the chamber 2, or may be arranged outside of the chamber 2 and detect the droplet 27 through a window (not shown) arranged on a wall of the chamber 2. The target sensor 4 includes a light receiving optical system (not shown) and an imaging unit (not shown) such as a charge-coupled device (CCD) or a photodiode. In order to improve the detection accuracy of the droplet 27, the light receiving optical system forms an image of the trajectory of the droplet 27 and the periphery of the droplet 27 on a light receiving surface of the imaging unit. A light source (not shown) is arranged to improve the contrast in the field of view of the target sensor 4. When the droplet 27 passes through the concentration region of the light from the light source, the imaging unit detects a change in the light passing through the trajectory of the droplet 27 and the periphery thereof. The imaging unit converts the detected light change into an electric signal. The electric signal may include image data of the droplet 27. The imaging unit outputs the electric signal to the processor 5.

The chamber 2 includes a gas exhaust port 205 for exhausting the buffer gas. A gas supply port 202 is connected to the gas supply unit 40 that supplies the buffer gas. The gas exhaust port 205 is connected to a gas exhaust unit 50 that exhausts the buffer gas.

The processor 5 of the present disclosure is a processing device including a memory 501 in which a control program and the like are stored and a central processing unit (CPU) 502 that executes the control program. The processor 5 is specifically configured or programmed to perform various processes included in the present disclosure and controls the entire extreme ultraviolet light generation system 11. The processor 5 receives a signal related to the pressure at the internal space of the chamber 2 measured by the pressure sensor 30, a signal related to image data of the droplet 27 imaged by the detection unit, a burst signal instructing the burst operation from the exposure apparatus 200, and the like. The processor 5 processes the various signals, and may control, for example, timing at which the droplet 27 is output, an output direction of the droplet 27, and the like. Further, the processor 5 may control the output timing of the laser device 3, the travel direction and the concentration position of the pulse laser light 31, and the like. The above-described various kinds of control are merely examples, and as will be described later, other control may be added as necessary.

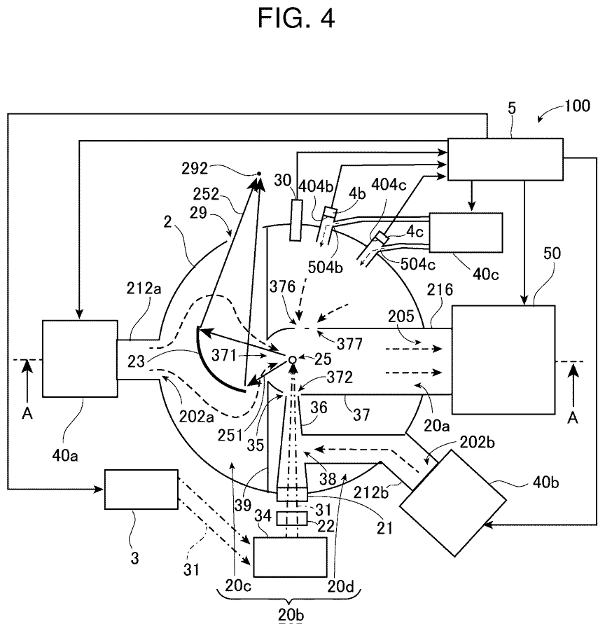

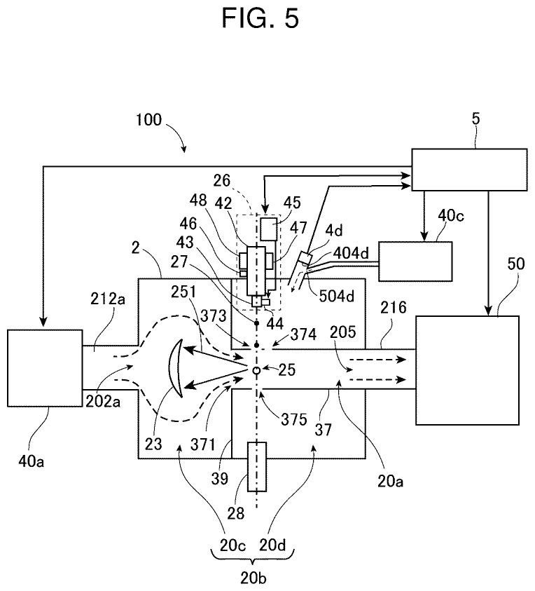

FIGS. 4 and 5 show in detail the configuration of the extreme ultraviolet light generation apparatus 100 including the chamber 2 according to the comparative example. Any component same as that described with reference to FIG. 3 is denoted by an identical reference sign, and duplicate description thereof is omitted. The extreme ultraviolet light generation apparatus 100 of the present comparative example operates in the same principle as the extreme ultraviolet light generation system 11 of FIG. 3, but is mainly different in the configuration that a first partition wall 37 and a second partition wall 39, which will be described later, are included. Further, the optical path of the pulse laser light 31 indicated by a one-dot chain line is also different from that of FIG. 3. FIG. 4 shows the configuration viewing in a trajectory direction of the droplet 27, and FIG. 5 shows the configuration viewing in an optical axis direction of the pulse laser light 31. FIG. 5 corresponds to a cross-sectional configuration at a position along line A-A of FIG. 4. Since line A-A of FIG. 4 passes substantially through the center of the EUV light concentrating mirror 23, the EUV light concentrating mirror 23 is shown in a substantially semi-elliptical shape in FIG. 5.

As shown in FIG. 4, in the extreme ultraviolet light generation apparatus 100, the first partition wall 37 and the second partition wall 39 are arranged at the internal space of the chamber 2. The first partition wall 37 is arranged to partition a first space 20a including the plasma generation region 25 in the chamber 2 and a second space 20b in which sensors 4b, 4c, 4d and the pressure sensor 30 are arranged. The first partition wall 37 may be referred to as a debris shield because of having a function to suppress diffusion of tin debris into the chamber 2. The second partition wall 39 separates the second space 20b in the chamber 2 into a third space 20c and a fourth space 20d.

The first partition wall 37 is made of stainless steel or metal molybdenum. The first partition wall 37 has a cylindrical shape. The first partition wall 37 penetrates the side surface of the chamber 2.

A part of the first partition wall 37 is a cylindrical body located inside the chamber 2, and is arranged to cover the plasma generation region 25. That is, the plasma generation region 25 is located in a through hole of the cylindrical body. In the chamber 2, the first partition wall 37 has openings 371 to 377. The openings 371 to 377 provide communication between the first space 20a in the chamber 2 and inside the first partition wall 37 and a space around the first partition wall 37. The opening 371 is an opening through which the radiation light 251 including the EUV light 252 passes. The opening 372 is an opening through which the pulse laser light 31 passes. The opening 373 and the opening 375 are openings through which the droplet 27 passes. The openings 374, 376, 377 are openings for sensors. Here, the opening 371 is a first cylindrical body opening provided at an end part on a side opposite to the gas exhaust unit 50 side.

According to the configuration of the extreme ultraviolet light generation apparatus 100, it is possible to suppress tin from adhering to the EUV light concentrating mirror 23 and the sensors 4b, 4c, 4d. Further, the EUV light concentrating mirror 23 is not provided with a through hole through which the pulse laser light 31 passes. The plasma generation region 25 is located inside the first partition wall 37 at a position between the target supply unit 26 and the target collection unit 28.

The sensors 4b, 4c, 4d are attached to the chamber 2. Each of the sensors 4b, 4c, 4d is a sensor similar to the target sensor 4. In the present specification, the sensor 4b, the sensor 4c, and the sensor 4d may be individually referred to as the target sensor 4. Although not shown, each of the sensors 4b, 4c, 4d may include an image sensor or an optical sensor, and an optical system that forms an image at the plasma generation region 25 inside the first partition wall 37 or the vicinity thereof on the image sensor or the optical sensor. The sensors 4b, 4c, 4d include detection windows 404b, 404c, 404d which transmit light at the internal space side of the chamber 2, respectively. Buffer gas supply ports 504b, 504c, 504d which are buffer gas outlets are arranged in the vicinity of the detection windows 404b, 404c, 404d of the sensors 4b, 4c, 4d, respectively. The buffer gas supply ports 504b, 504c, 504d are connected to a gas supply unit 40c. Contamination of the sensors 4b, 4c, 4d is suppressed by outputting the buffer gas from the vicinity of the detection windows 404b, 404c, 404d toward the inside of the chamber 2 as indicated by dashed arrows. Instead of the sensor, a light source that illuminates the plasma generation region 25 with visible light may be arranged at a position of any one of the sensors 4b, 4c, 4d.

The openings 374, 376, 377 are located between the plasma generation region 25 and the sensors 4d, 4b, 4c, respectively. Accordingly, light emitted from the plasma generation region 25 or the vicinity thereof reaches the sensors 4d, 4b, 4c. Alternatively, light emitted from a light source located at the position of the one of the sensors 4d, 4b, 4c reaches the plasma generation region 25. Thus, the openings 374, 376, 377 allow light for observing a part of the first space 20a to pass therethrough.

The EUV light concentrating mirror 23 is located in the third space 20c in the chamber 2 and outside the first partition wall 37. The opening 371 of the first partition wall 37 is located on the optical path of the radiation light 251 generated at the plasma generation region 25 and directed toward the EUV light concentrating mirror 23. The connection portion 29 is located on the optical path of the EUV light 252 directed toward the intermediate focal point 292 from the EUV light concentrating mirror 23.

The chamber 2 includes a first gas supply port 202a, a second gas supply port 202b, and the gas exhaust port 205. Here, the second gas supply port 202b is also referred to as a second opening. The first gas supply port 202a is connected to the gas supply unit 40a via a first gas supply pipe 212a. The second gas supply port 202b is connected to the gas supply unit 40b via a second gas supply pipe 212b. The buffer gas is supplied to the third space 20c via the first gas supply port 202a, and the buffer gas is supplied to the first space 20a and the fourth space 20d via the second gas supply port 202b and a laser light path pipe 36. The laser light path pipe 36 corresponds to the optical path pipe in the present disclosure. The gas supply unit 40a and the gas supply unit 40b may be configured to be used in common, and the flow rate of the buffer gas from each gas supply port may be controlled by the processor 5 controlling the gas flow rate adjustment unit provided in each gas supply pipe. In the present specification, the gas supply units 40a, 40b, 40c may be collectively referred to as the gas supply unit 40.

The first partition wall 37 is a cylindrical body and serves as an exhaust pipe for exhausting the buffer gas in the chamber 2 to the outside of the chamber 2. The opening 371 functions as an inlet port for the buffer gas to be exhausted. The first partition wall 37 is provided with the gas exhaust port 205 which is a second cylindrical body opening, and the gas exhaust port 205 is connected to the gas exhaust unit 50 via an exhaust pipe 216. The exhaust pipe 216 may be integrally formed with the first partition wall 37.

The gas exhaust unit 50 exhausts the gas in the first space 20a inside the first partition wall 37 to the space outside the chamber 2 and outside the first partition wall 37 through the gas exhaust port 205. As a result, the pressure in the first space 20a is maintained lower than the pressure in the second space 20b. Consequently, through the openings 371 to 377, the buffer gas flows from the second space 20b toward the first space 20a as indicated by dashed arrows in FIGS. 4 and 5.

The buffer gas supplied from the second gas supply port 202b passes through the openings 372 to 377, passes in the vicinity of the plasma generation region 25, and is exhausted to the outside of the chamber 2. Therefore, movement of tin debris from the first space 20a to the second space 20b is suppressed, and accumulation of the tin debris on the EUV light concentrating mirror 23 or the like is suppressed.

The processor 5 is electrically connected to the following configurations and performs specific functions. That is, a supply amount of the gas is controlled for the gas supply units 40a, 40b, an exhaust amount of the gas is controlled for the gas exhaust unit 50, and a pulse energy and a pulse interval of the laser light are controlled for the laser device 3. Further, the processor 5 controls output of the droplet 27 and combining of the droplet 27 for the target supply unit 26. Further, the processor 5 receives detection signals from the sensors 4b, 4c, 4d, and calculates control amounts of the laser device 3 and the target supply unit 26 based on the detection signals.

The droplet 27 output from the target supply unit 26 passes through the opening 373 and reaches the plasma generation region 25. The droplet 27 not irradiated with the pulse laser light 31 passes through the plasma generation region 25, passes through the opening 375, and is collected by the target collection unit 28.

The pulse laser light 31 having passed through the laser light path pipe 36 and output from the first opening 35 of the laser light path pipe 36 passes through the opening 372, travels to the inside of the first partition wall 37, and is radiated to the droplet 27 in the plasma generation region 25. The second gas supply pipe 212b is connected to a gas inlet port 38 of the laser light path pipe 36, and the buffer gas supplied from the gas supply unit 40b is discharged from the first opening 35 of the laser light path pipe 36 toward the opening 372. Most of the buffer gas flows into the first space 20a, but a part thereof flows into the fourth space 20d.

The gas supply unit 40a supplies the buffer gas from the first gas supply port 202a to the third space 20c. The flow rate of the buffer gas at the first gas supply port 202a is, for example, not less than 40 nlm and not more than 60 nlm. While the laser device 3 is in operation, the gas supply units 40a, 40b continue to supply the gas to the chamber 2, and the gas exhaust unit 50 continues to exhaust the gas in the chamber 2 from the chamber 2.

### 3.2 Operation

Referring back to FIG. 3, operation of the exemplary LPP extreme ultraviolet light generation system 11 will be described. Here, the extreme ultraviolet light generation apparatus 100 described with reference to FIG. 3 and the extreme ultraviolet light generation apparatus 100 described in detail with reference to FIGS. 4 and 5 operate in a similar manner.

The target supply unit 26 outputs the droplet 27 formed of a target substance toward the plasma generation region 25 at the internal space of the chamber 2. The droplet 27 is irradiated with the pulse laser light 31. The droplet 27 irradiated with the pulse laser light 31 is turned into plasma, and the radiation light 251 is radiated from the plasma. The EUV light 252 contained in the radiation light 251 is reflected by the EUV light concentrating mirror 23 with higher reflectance than light in other wavelength ranges. The EUV light 252 reflected by the EUV light concentrating mirror 23 is concentrated at the intermediate focal point 292, which is the second focal point, and output to the external apparatus 6. Here, one droplet 27 may be irradiated with a plurality of pulses included in the pulse laser light 31.

When the droplet 27 is turned into plasma, fine particles and charged particles of tin are generated, and some of them adhere to the surfaces of the EUV light concentrating mirror 23 and other components. Hereinafter, fine particles and charged particles of tin are referred to as “tin debris”. While the extreme ultraviolet light generation system 11 is in operation, the gas supply unit 40 continues to supply the buffer gas to the chamber 2, and the gas exhaust unit 50 continues to exhaust the buffer gas in the chamber 2 from the chamber 2. When the buffer gas is a hydrogen gas, radicals or ions generated from the hydrogen gas react with the tin constituting the tin debris and a stannane (SnH₄) gas is generated. In this course, the tin adhering to the EUV light concentrating mirror 23 and other components is removed. The stannane gas and the unreacted hydrogen gas are exhausted to the outside of the chamber 2 by the gas exhaust unit 50.

The processor 5 controls the entire extreme ultraviolet light generation system 11. The processor 5 controls the passage timing, the trajectory, the position, the size, and a plasma point of the droplet 27 based on the detection result of the target sensor 4. Further, the processor 5 controls the output timing, the concentration position, and the intensity of the pulse laser light 31, the gas supply unit 40, and the gas exhaust unit 50. The processor 5 controls the gas supply unit 40 and the gas exhaust unit 50 so that the inside of the chamber 2 becomes a predetermined pressure based on the detection result of the pressure sensor 30.

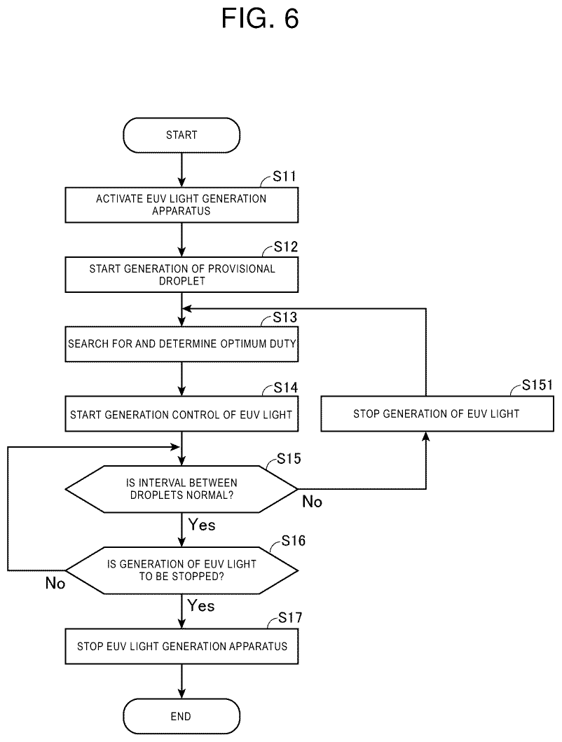

FIG. 6 is a flowchart showing operation of the extreme ultraviolet light generation system 11 of the comparative example.

### (Step S11)

The present step is an activation step of the extreme ultraviolet light generation system 11. When the extreme ultraviolet light generation system 11 is activated, the processor 5 activates the gas supply unit 40 and the pressure sensor 30, and supply of the buffer gas to the chamber 2 in a vacuum state is started. The processor 5 starts control of the gas supply unit 40 and the gas exhaust unit 50 to be described later so that the pressure in the fourth space 20d becomes constant at a predetermined gas pressure.

The processor 5 activates the gas exhaust unit 50, and inflow of the buffer gas from the respective openings to the first space 20a in the vacuum state is started. The buffer gas having flowed in is exhausted to the outside of the chamber 2.

The processor 5 activates the heater 47 and starts heating control of the target in the tank 42. The processor 5 controls the heater 47 so that the target is maintained at a predetermined melt temperature after reaching the melting temperature. When the target is tin, the predetermined melt temperature is a temperature in the range of 232° C. to 300° C.

The processor 5 activates the pressure regulator 48 and starts supply control of an inert gas into the tank 42. The processor 5 controls the pressure in the tank 42 to be maintained at a predetermined pressure after reaching the predetermined pressure. When the target is tin, the predetermined pressure is a pressure in the range of 0.2 MPa to 40 MPa. In a state of reaching the pressure, a jet-like liquid tin is output from the nozzle 43.

The processor 5 activates the piezoelectric element power source 45, and supply of driving power to the piezoelectric element 44 is started. As the driving power, an electric signal of a rectangular wave causing the piezoelectric element 44 to vibrate at a predetermined frequency is output. The nozzle 43 vibrates in accordance with the vibration of the piezoelectric element 44. The electric signal is controlled to have a duty at which the liquid target output from the nozzle 43 is separated and the separated targets are combined to form a droplet. A target duty at the time of activation is a provisional duty obtained in advance, and this is hereinafter referred to as a provisional duty. An optimum duty is re-selected in a later step.

The processor 5 activates the target sensor 4 so that the detection signal can be output. The processor 5 starts monitoring whether or not the interval and the diameter of the passing target is normal and whether or not the position and the intensity of the generated EUV light 252 maintain to have a predetermined stability.

The processor 5 activates the laser device 3 and the laser light transmission device 34, and the control is started so that predetermined pulse laser light is radiated to the plasma generation region 25 when a light emission trigger signal is applied.

In the present specification, time corresponding to step S11, step S12, and step S13 is defined as the time of activation of the extreme ultraviolet light generation system 11.

### (Step S12)

The present step is a step in which the processor 5 starts generation control of a provisional droplet. In a state of being in a predetermined state, the liquid tin separates and combining of the separated targets starts. Hereinafter, the target in the combined state is also simply referred to as the droplet 27. The droplet 27 generated by the provisional duty is referred to as a provisional droplet 27p. The diameter of the provisional droplet 27p and the interval between adjacent provisional droplets 27p are also provisional, and are changed to target values in a later step. Therefore, most of the monitoring results in the present step indicate “abnormal”.

### (Step S13)

The present step is a step in which the processor 5 performs control so as to cause the piezoelectric element 44 of the target supply unit 26 to search for the optimum duty. As a search method, for example, abnormal value occurrence rates with the provisional droplet 27p at respective duties are calculated by first changing the duty from 1% to 99% by a predetermined step amount, for example, in increments of 0.1%. Then, a duty of a center value of a widest region among continuous duty ranges in which the abnormal value occurrence rates are less than a threshold value is determined to be the optimum duty. The present step is executed by the processor 5 based on the detection signal from the target sensor 4.

The term “abnormal” herein refers to abnormality in the diameter of the provisional droplet 27p and the interval between adjacent provisional droplets 27p.

In the present specification, a period in which the pulse laser light 31 is not radiated to the droplet 27 during a period in which the target supply unit 26 outputs the droplet 27 is referred to as a first period. The first period is a period including at least a part of a search period for searching for and determining the optimum duty of the electric signal to be applied to the piezoelectric element 44.

### (Step S14)

The present step is a step in which the processor 5 starts generation control of the EUV light 252. The processor 5 operates the duty on the basis of the optimum duty, and starts control to maintain the combining state of the droplet 27 using the abnormal value occurrence rate as a control amount. Then, irradiation of the droplet 27 with the pulse laser light 31 is started, and the radiation light 251 is generated. The droplet 27 generated with the optimum duty is not the provisional droplet 27p as described above, but a droplet 27 that stably generates the EUV light 252. The processor 5 performs control by adjusting, based on the detection signal of the target sensor 4, the intensity or the optical axis of the pulse laser light 31 and the trajectory of the droplet 27 so that the position at which the EUV light 252 is generated or the intensity of the EUV light 252 becomes a predetermined value.

### (Step S15)

The present step is a step in which the processor 5 determines whether or not the interval between the droplets 27 is normal. Further, in the present step, it may be determined whether or not the stability of the EUV light 252 is normal. Specifically, it is determined whether or not the intensity of the EUV light 252 or the stability of the generation position is normal. In a state of being out of a range of threshold values, it is determined to be abnormal and step S151 is executed, and in a state of being within the range of the threshold values, it is determined to be normal and step S16 is executed.

### (Step 151)

The present step is a step in which the processor 5 performs control to stop generation of the EUV light 252. The processor 5 stops generation of an oscillation trigger signal of the pulse laser light 31, and stops generation of the EUV light 252. In other words, the period in which the processor 5 determines that the interval between the droplets 27 is abnormal and generation of the EUV light 252 is stopped is a period in which the pulse laser light 31 is not radiated to the droplet 27 during the period in which the target supply unit 26 outputs the droplet 27. Although the duty at this time remains at an optimum duty 1 set first, processing returns to step S13 to search for and determine a new optimum duty 2 as treating that the provisional droplet 27p is being generated.

### (Step S16)

The present step is a step in which the processor 5 is to receive a request to stop generation of the EUV light 252. When a request to stop generation of the EUV light 252 is received, processing proceeds to step S17, and when a request to stop generation of the EUV light 252 is not received, processing returns to step S15.

### (Step S17)

The present step is a step in which the processor 5 performs stop control of the extreme ultraviolet light generation apparatus 100.

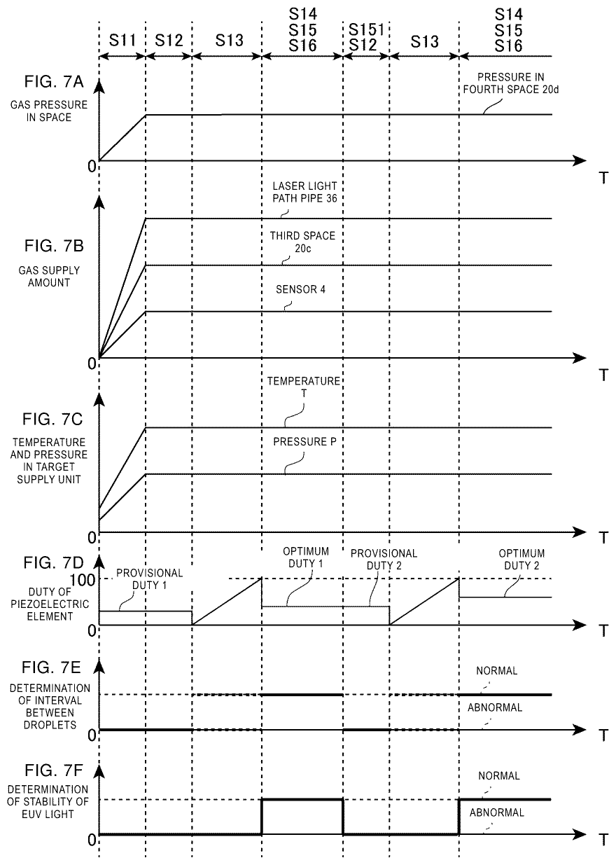

FIGS. 7A to 7F show timing charts showing state changes of respective configurations when steps S11 to S16 of FIG. 6 are executed. In FIGS. 7A to 7F, the horizontal axis represents the elapse of time, and the time is common. Dashed lines indicate points of change of a state. The number with S in the upper row is the number of the step executed between adjacent broken lines.

In FIG. 7A, the vertical axis represents the pressure in the fourth space 20d. After step S11 in which the extreme ultraviolet light generation apparatus 100 is activated, the pressure in the fourth space 20d is maintained substantially constant after step S12.

In FIG. 7B, the vertical axis represents a gas supply amount. Specifically, the gas supply amount supplied from the gas supply unit 40b via the laser light path pipe 36, the gas supply amount supplied from the gas supply unit 40a via the first gas supply port 202a, and the gas supply amount supplied from the gas supply unit 40c via the buffer gas supply ports 504b, 504c, 504d arranged in the vicinity of the target sensor 4 are shown. The three gas supply amounts are maintained constant in and after step S12.

In FIG. 7C, the vertical axis represents a temperature T and a pressure P in the vicinity of the target supply unit 26. The temperature T and the pressure P are maintained substantially constant in and after step S12.

FIG. 7D shows transition of the duty of the piezoelectric element 44. Specifically, the voltage of the piezoelectric element power source 45 applied to the piezoelectric element 44 is set to a predetermined voltage with the duty changed from 0% to 100%. Since the duty changes between 0% and 100% due to the search operation in the period of step S13, the transition is represented to have a slope. In the period of step S14, a state in which the optimum duty 1 is selected based on the search result is shown. The duty in the period of step S151 is the same value as the optimum duty 1 in the period of step S14, but it is no longer the optimum duty because the stability of the EUV light 252 is determined to be abnormal in this period as shown in FIG. 7F. Based on the above, the duty in this period is referred to as a provisional duty 2 to be distinguished from the optimum duty 1. The provisional duty 2 may be changed to the same value as the provisional duty 1 in the period of step S12 if separated targets are combined.

FIG. 7E shows transition of the determination result of whether or not the interval between adjacent droplets 27 is normal. In the period of step S12, while the electric signal with the provisional duty 1 is applied to the piezoelectric element 44, the provisional droplet 27p is generated after the pressure in the fourth space 20d, the gas supply amounts from the respective configurations, the temperature T of the target supply unit 26, and the pressure P reach predetermined values, respectively. The interval between the provisional droplets 27p is determined to be “abnormal”. In the period of step S13, “normal” and “abnormal” are randomly determined depending on the time due to the search operation of the optimum duty. In order to indicate this state, this period is indicated by dashed lines in both “normal” and “abnormal”. In the period of step S14, the laser light is radiated with the optimum duty.

FIG. 7F shows transition of stability determination of the EUV light 252. In the periods of steps S14 to S16, the EUV light 252 is stably emitted, and the determination result indicates “normal”. Irradiation of the laser light is continued as long as the interval between the droplets 27 is determined to be “normal” as shown in FIG. 7E, and when it is determined to be “abnormal” in course of time, the stability of the EUV light 252 is also determined to be “abnormal” as shown in FIG. 7F. When it is determined that the stability of the EUV light 252 is abnormal, the interval between the droplets 27 is also in the “abnormal” state, and when it is determined that the stability of the EUV light 252 is “abnormal”, the duty shown in FIG. 7D is also treated as the provisional duty 2.

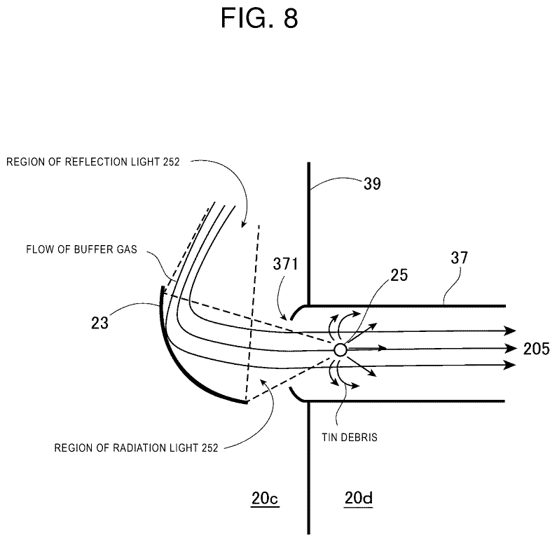

FIG. 8 is a partially enlarged view of FIG. 4 in steps S14, S15, S16 of FIG. 6. The third space 20c in which the EUV light concentrating mirror 23 is arranged communicates with the gas exhaust port 205 through the opening 371. The position and opening diameter of the opening 371 are set so that the opening 371 faces the entire reflection surface of the EUV light concentrating mirror 23 from f the plasma generation region 25. Therefore, the buffer gas exhausted through the first partition wall 37 travels from all positions of the reflection surface of the EUV light concentrating mirror 23 toward the plasma generation region 25. In other words, the buffer gas travels in the region of the radiation light 251 surrounded by the plasma generation region 25 and the reflection surface of the EUV light concentrating mirror 23 in a direction approximately opposite to the radiation light 251.

Some of the tin debris generated by plasmatization travels toward the EUV light concentrating mirror 23, but is stopped before the EUV light concentrating mirror 23 as being blocked by the flow of the buffer gas, and then, is eventually exhausted together with the buffer gas. Thus, contamination is suppressed at every position of the reflection surface of the EUV light concentrating mirror 23.

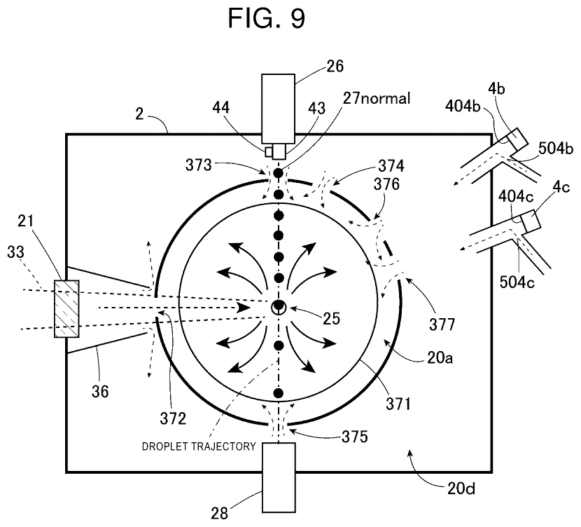

FIG. 9 is a partially enlarged view of FIG. 5 in steps S14, S15, S16 of FIG. 6 as viewing FIG. 5 from the opening 371 side. The buffer gas supplied from the second gas supply port 202b flows into the first space 20a inside the first partition wall 37 from the openings 372 to 377, and is exhausted to the outside of the chamber 2. By causing such a flow of the gas, intrusion of tin debris into the fourth space 20d is suppressed, and contamination of elements such as the sensors 4b to 4d and the window 21b is suppressed. When the stability of the EUV light 252 generated during circulation of steps S15 to S16 is normal, it is determined that the interval between the droplets 27 is also normal. It is considered that the diameter of the droplets 27 whose interval is determined to be normal is constant. In the drawings, the droplet 27 having a size of this diameter is indicated as a droplet 27normal. The trajectory of the droplet 27normal is influenced by the buffer gas flowing into the first space 20a to some extent. However, since the flow rate of the buffer gas from the respective openings in steps S14, S15, S16 is limited to a flow rate at which the droplet 27normal is collected by the target collection unit 28, all of the droplets 27normal not irradiated with the laser light reaches the target collection unit 28.

### 3.3 Problem

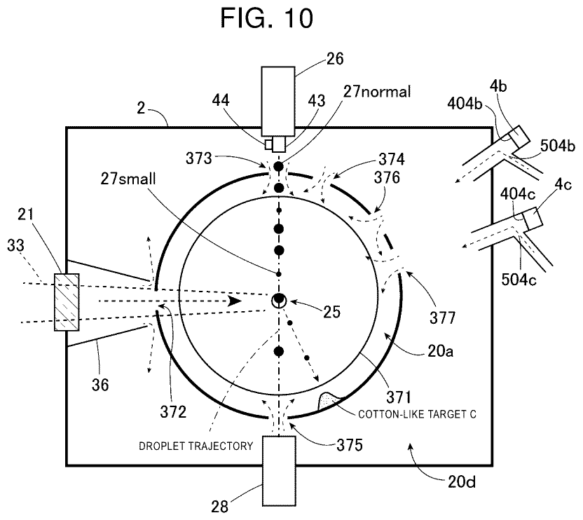

FIG. 10 is a partially enlarged view of FIG. 3 in steps S11 to S13 and steps S151 to S13 of FIG. 6. As shown in FIGS. 7D, 7E, and 7F, the interval between the droplets 27 often indicates “abnormal” because the state of some configuration elements is not stable or is provisional. When the interval between the droplets 27 is abnormal, a droplet 27small whose diameter is smaller than the diameter of the droplet 27normal is often generated.

As shown in FIGS. 8 and 10, since the buffer gas flows from the respective openings in the period of the above steps as well, the droplet 27small generated in this period is influenced by the buffer gas flow and the trajectory thereof is greatly deviated. When the trajectory is deviated, the droplet 27small is not collected by the target collection unit 28 and reaches the inner wall of the first partition wall 37 to contaminate the inside. For example, the droplet 27small adhering to the wall surface forms a cotton-like target C on the inner wall. There is a possibility that the cotton-like target C grows in size as the operation time elapses to interfere with the optical path of the EUV light 252, the optical path to the target sensor 4, and the trajectory of the droplet 27. A part of the grown cotton-like target C is separated by the buffer gas flow and adheres to the opening, so that the EUV light 252 cannot be generated in course of time.

Therefore, in the following embodiments, the extreme ultraviolet light generation apparatus 100 in which contamination in the chamber 2 during operation is suppressed is exemplified.

### 4. Description of Extreme Ultraviolet Light Generation Apparatus of First Embodiment

### 4.1 Configuration

The configuration of the extreme ultraviolet light generation apparatus 100 of a first embodiment will be described. Any component same as that described above is denoted by an identical reference sign, and duplicate description thereof is omitted unless specific description is needed.

The extreme ultraviolet light generation apparatus 100 of the present embodiment differs from the extreme ultraviolet light generation apparatus 100 of the comparative example only in the control of the supply amount of the buffer gas to the laser light path pipe 36, but is similar in configuration. Therefore, description of the entire configuration of the extreme ultraviolet light generation apparatus 100 of the present embodiment will be omitted. However, in the present embodiment, the gas supply unit 40b is deemed to be replaced with a first gas supply unit 40b.

### 4.2 Operation

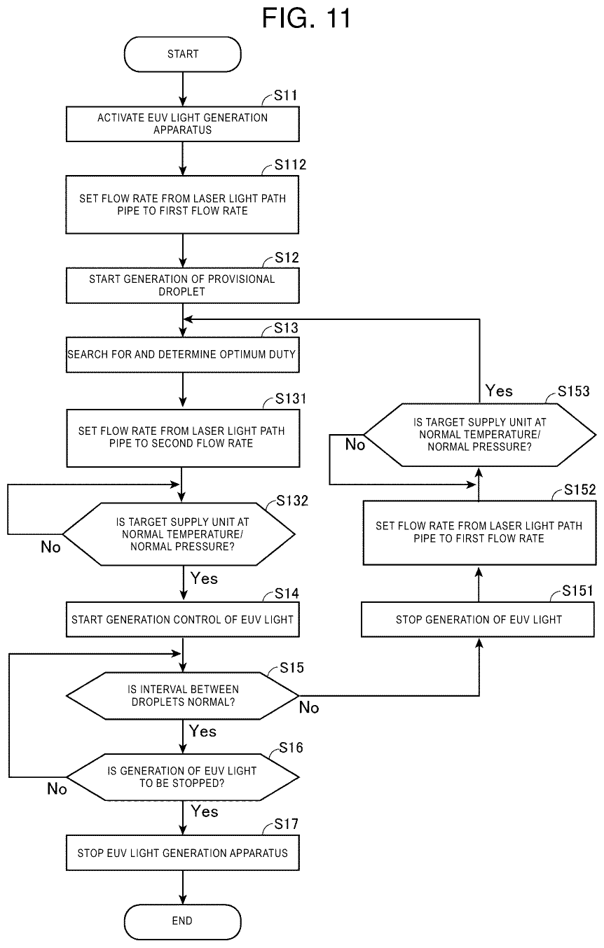

FIG. 11 is a flowchart showing operation of the extreme ultraviolet light generation system 11 of the present embodiment. As the operation with the same step number as in the flowchart of FIG. 6, similar operation as in FIG. 6 is performed. FIG. 11 differs from the flowchart described in FIG. 6 in including steps S112, S131, S132, S152, and S153 in the control flow.

In the present specification, the flow rate of the buffer gas supplied from the first gas supply unit 40b in the above-described first period is referred to as a first flow rate. Further, the flow rate of the buffer gas supplied from the first gas supply unit 40b in a second period which is a period in which the pulse laser light 31 is radiated to the droplet 27, during the period in which the target supply unit 26 outputs the droplet 27, is referred to as a second flow rate.

The processor 5 sets a target flow rate of the buffer gas to be supplied from the first gas supply unit 40b to the laser light path pipe 36 in the period of activation to the first flow rate, and sets a target flow rate of the buffer gas to be supplied from the first gas supply unit 40b in a period in which the pulse laser light 31 is radiated to the droplet 27 to the second flow rate. The processor 5 sets the flow rate of the buffer gas such that the first flow rate is smaller than the second flow rate.

### (Step S112)

The present step is a step in which the processor 5 controls the flow rate of the buffer gas to be supplied from the first gas supply unit 40b via the laser light path pipe 36 to the first flow rate.

### (Step S131)

The present step is a step in which the processor 5 controls the flow rate of the buffer gas to be supplied from the first gas supply unit 40b via the laser light path pipe 36 to the second flow rate.

### (Step S132)

The present step is a step in which the processor 5 causes the extreme ultraviolet light generation apparatus 100 to wait until the target supply unit 26 reaches a normal temperature and a normal pressure. Here, the normal temperature and the normal pressure are a target temperature and a target pressure when the extreme ultraviolet light generation system 11 operates normally, and may be predetermined and stored in the memory 501. When the target supply unit 26 has reached the normal temperature and the normal pressure, processing proceeds to step S14. When the target supply unit 26 has not reached the normal temperature and the normal pressure, the processor 5 continues S132.

### (Step S152)

The present step is a step in which the processor 5 sets the target flow rate of the buffer gas to be supplied from the first gas supply unit 40b to the first flow rate.

### (Step S153)

The present step is a step in which the processor 5 causes waiting until the target supply unit 26 reaches the normal temperature and the normal pressure. When the target supply unit 26 has not reached the normal temperature and the normal pressure, the processor 5 continues S153. When the target supply unit 26 has reached the normal temperature and the normal pressure, processing proceeds to step S13.

Although the duty remains at the optimum duty 1 set first in step S153, processing returns to step S13 to search for and determine the new optimum duty 2 as treating that the provisional droplet 27p is being generated.

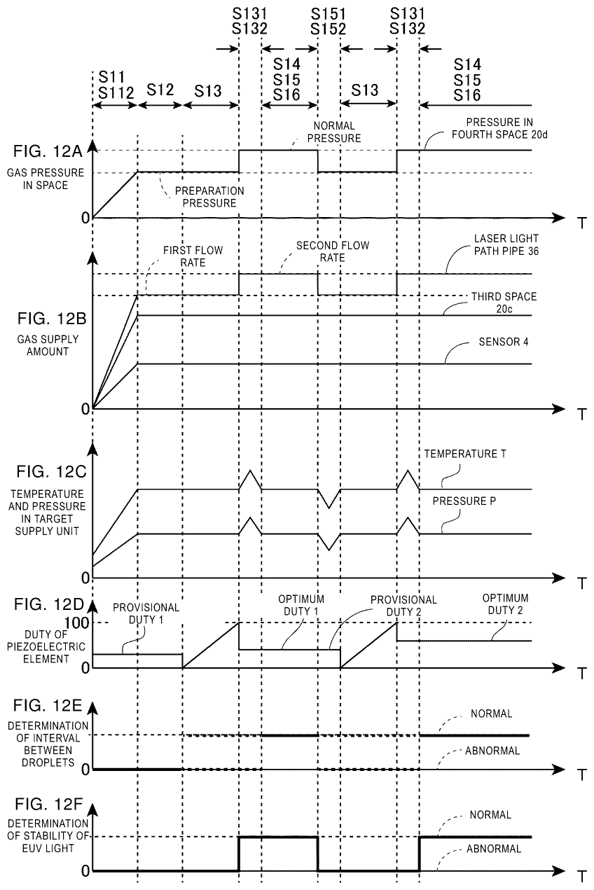

FIGS. 12A to 12F show timing charts showing state changes of respective configurations when steps S11 to S16 of FIG. 11 are executed. The horizontal axis in each chart represents the elapse of time, and the time is common. Dashed lines indicate points of change of a state. The number with S in the upper row is the number of the step executed between adjacent broken lines.

In FIG. 12A, transition of the pressure in the fourth space 20d is shown. Here, in steps S131 and S132 and in steps S14, S15, and S16, the pressure is at the normal pressure. On the other hand, in steps S12 and S13, the pressure is at a preparation pressure which is lower than the normal pressure. This is because, in the latter period, the supply amount of the buffer gas supplied from the first gas supply unit 40b via the laser light path pipe 36 is the first flow rate, and is smaller than the second flow rate which is the supply amount of the gas in the former period.

In FIG. 12B, transition of the gas supply amount supplied from the laser light path pipe 36 differs from that in FIG. 7B. The gas supply amount supplied from the laser light path pipe 36 is the second flow rate in steps S131 and S132 and in steps S14, S15, and S16. On the other hand, in steps S12 and S13, it is the first flow rate which is smaller than the second flow rate.

FIG. 12C differs from FIG. 7C in that the temperature and the pressure temporarily vary in steps S131 and S132 and in steps S151 and S152. The former is caused by the fact that the gas supply amount supplied from the laser light path pipe 36 varies from the first flow rate, which is the preparation flow rate, to the second flow rate, which is the normal flow rate, the pressure of the buffer gas varies, the heat transfer state from the heater 47 of the target supply unit 26 to the buffer gas changes, and the temperature and the pressure of the target supply unit 26 also vary. The latter is caused by the fact that the gas supply amount supplied from the laser light path pipe 36 varies inversely from the second flow rate to the first flow rate.

### 4.3 Effect

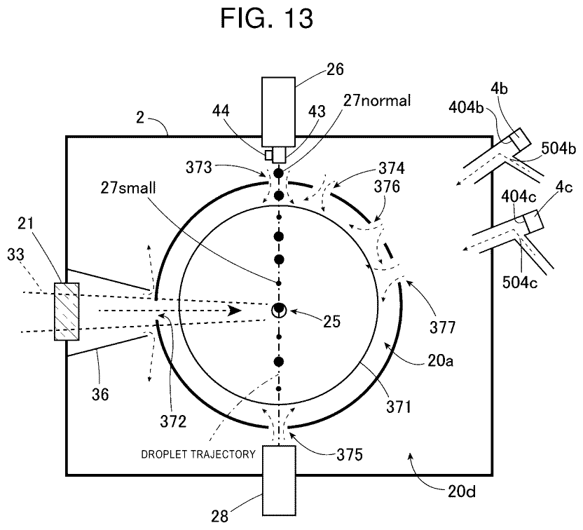

FIG. 13 is a schematic view showing a case in which the droplet 27small having a small diameter is output in the first embodiment. The period in which the droplet 27small may be output is the time of activation of the extreme ultraviolet light generation apparatus 100, that is, the period of steps S11, S12, and S13, and the period in which generation of the EUV light 252 is stopped, that is, the period of steps S151 and S152. In the present embodiment, since the first flow rate, which is the supply amount of the buffer gas from the laser light path pipe 36, is smaller than the second flow rate in the above period, the droplet 27small having a light mass is also suppressed from being flowed by the flow of the buffer gas. Therefore, the trajectory of the droplet 27 can be suppressed from being varied by the supplied buffer gas, the droplet 27 can be easily collected by the target collection unit 28, and contamination of the chamber 2 can be suppressed.

### 4.4 First Modification

### 4.4.1 Configuration

A first modification of the first embodiment will be described. Since the configuration of the extreme ultraviolet light generation apparatus 100 of the first modification is similar to that of the first embodiment, description thereof will be omitted.

### 4.4.2 Operation

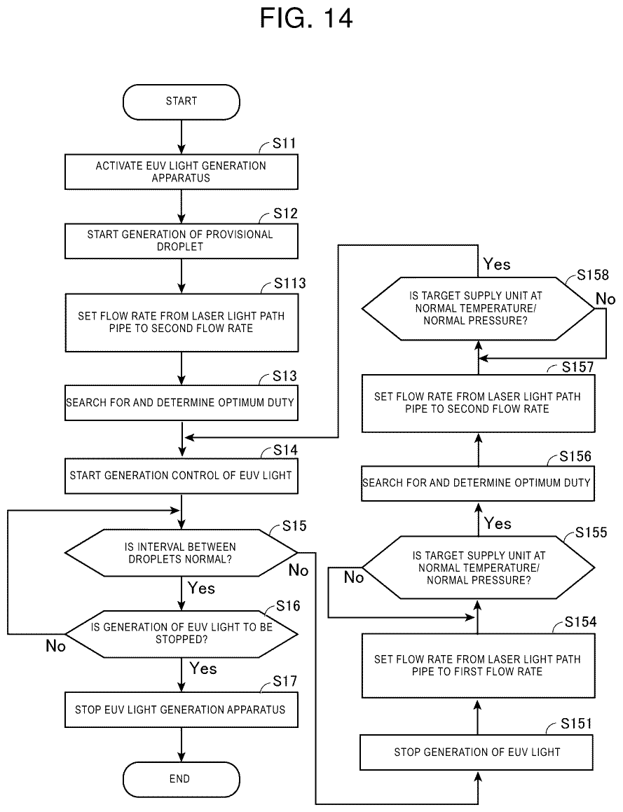

Next, operation of the first modification of the first embodiment will be described. FIG. 14 is a flowchart showing operation of the extreme ultraviolet light generation system 11 of the present modification. As the operation with the same step number as in the flowchart of FIG. 11, similar operation as in FIG. 11 is performed. The operation flow is different from that of the first embodiment in that the supply amount of the buffer gas from the laser light path pipe 36 is set to the second flow rate, which is the normal flow rate, at the time of activation. Further, the operation flow is different that of FIG. 11 in that, when generation of the EUV light 252 is stopped, the supply amount of the buffer gas from the laser light path pipe 36 is set to the first flow rate, which is smaller than the second flow rate, prior to the search for the new optimum duty.

Hereinafter, the flowchart of FIG. 14 will be described in terms of differences from that of FIG. 11.

### (Step S113)

The present step is a step in which the processor 5 sets the gas supply amount of the buffer gas from the laser light path pipe 36 to the second flow rate, which is the normal flow rate.

In the present modification, the period in which the pulse laser light 31 is not radiated to the droplet 27 during the period in which the target supply unit 26 outputs the droplet 27 is the period in which generation of the EUV light 252 is stopped. Operation in this period will be described below.

### (Step S154)

The present step is a step in which the processor 5 sets the target flow rate of the buffer gas to be supplied from the first gas supply unit 40b to the first flow rate, which is the preparation flow rate. Similarly to the first embodiment, the first flow rate is smaller than the second flow rate, which is the normal flow rate.

### (Step S155)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S155. When the target supply unit 26 has reached the normal temperature and the normal pressure, processing proceeds to step S156.

### (Step S156)

The present step is a step in which the processor 5 performs control so as to cause the piezoelectric element 44 of the target supply unit 26 to search for the optimum duty. Since the contents of operation are similar to those in step S13, description thereof will be omitted.

### (Step S157)

The present step is a step in which the processor 5 sets the target flow rate of the buffer gas to be supplied to the laser light path pipe 36 to the second flow rate.

### (Step S158)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S158. When the target supply unit 26 has reached the normal temperature and the normal pressure, processing proceeds to step S14.

### 4.4.3 Effect

According to the present modification, the flow rate of the buffer gas supplied from the first gas supply unit 40b to the laser light path pipe 36 is set to the second flow rate, which is the normal flow rate, in steps S12 and S13, which are the period during activation. Therefore, the extreme ultraviolet light generation apparatus 100 does not need to wait until the target supply unit 26 reaches the normal temperature and the normal pressure. Accordingly, the waiting time may be shortened.

### 4.5 Second Modification

### 4.5.1 Configuration

A second modification of the first embodiment will be described. Since the configuration of the extreme ultraviolet light generation apparatus 100 of the second modification is similar to that of the first embodiment, description thereof will be omitted.

### 4.5.2 Operation

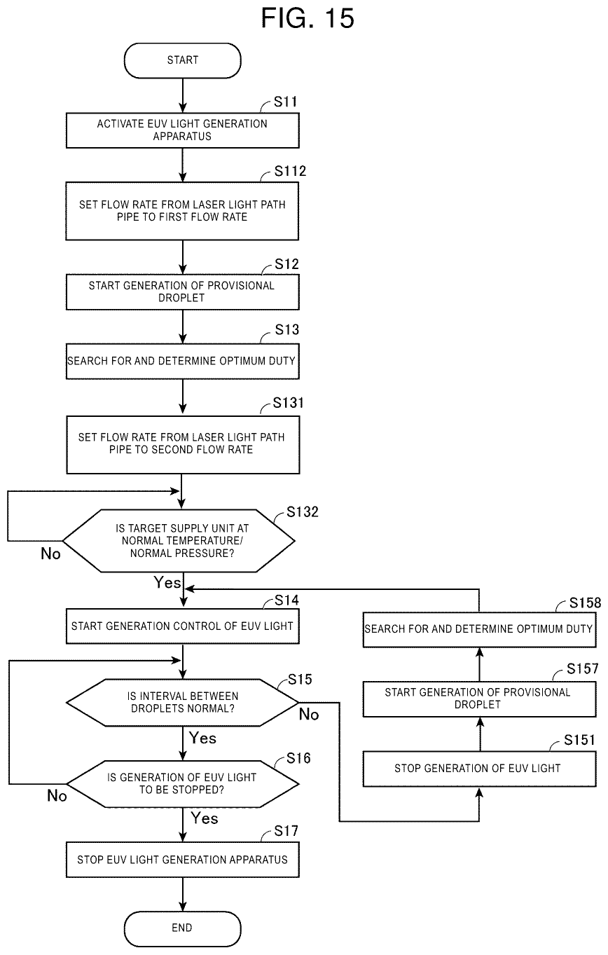

Next, operation of the second modification of the first embodiment will be described. FIG. 15 is a flowchart showing operation of the extreme ultraviolet light generation system 11 of the present modification. In the step with the same step number as in the flowchart of FIG. 11, similar operation is performed. The operation flow is different from that of the first embodiment in that the supply amount of the buffer gas from the laser light path pipe 36 is set to the first flow rate by the processor 5 only at the time of activation.

The flowchart of FIG. 15 will be described in terms of differences from that of FIG. 11. In the present modification, in the period in which the generation of the EUV light 252 is stopped while the target supply unit 26 outputs the droplet 27, that is, in steps S151, S159, and S160, the supply amount of the buffer gas from the laser light path pipe 36 is not changed from the second flow rate.

### (Step S157)

The present step is a step in which the processor 5 starts generation control of the provisional droplet 27p. Since operation is similar to that of step 12, description thereof will be omitted.

### (Step S158)

The present step is a step in which the processor 5 performs control so as to cause the piezoelectric element 44 of the target supply unit 26 to search for the optimum duty. Since operation is similar to that of step S13, description thereof will be omitted. After step S158, processing proceeds to step S14.

### 4.5.3 Effect

According to the present modification, the processor 5 does not set the flow rate of the buffer gas to be supplied from the first gas supply unit 40b to the laser light path pipe 36 to the first flow rate, which is smaller than the normal flow rate, in the period in which the target supply unit 26 outputs the droplet 27 and the pulse laser light 31 is not radiated to the droplet 27. Therefore, the extreme ultraviolet light generation apparatus 100 does not need to wait until the target supply unit 26 reaches the normal temperature and the normal pressure. Accordingly, the waiting time may be shortened.

### 5. Description of Extreme Ultraviolet Light Generation Apparatus of Second Embodiment

### 5.1 Configuration

A second embodiment will be described. Since the configuration of the extreme ultraviolet light generation apparatus 100 of the second embodiment is similar to that of the first embodiment, description thereof will be omitted.

### 5.2 Operation

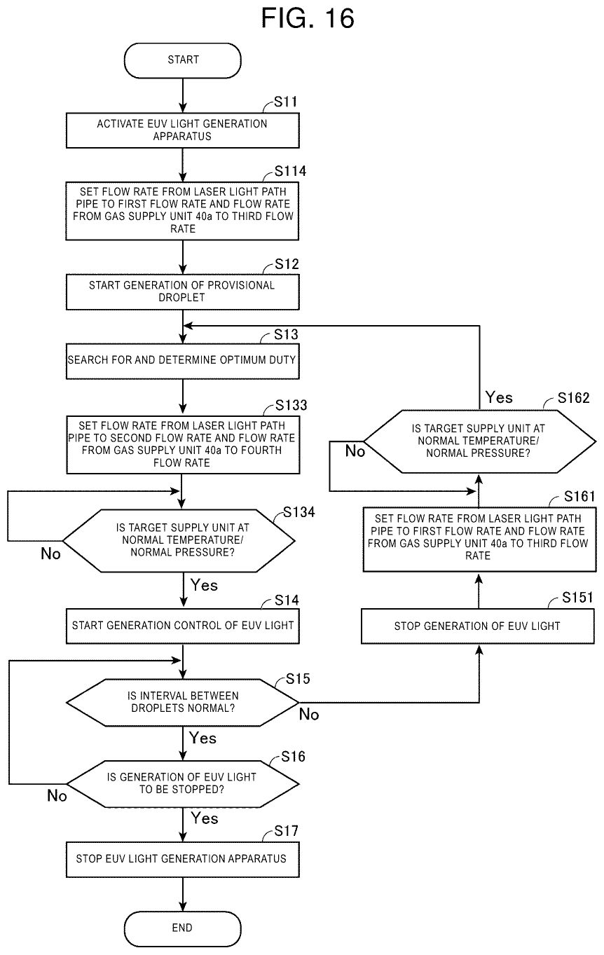

Next, operation of the second embodiment will be described. FIG. 16 is a flowchart showing operation of the extreme ultraviolet light generation system 11 of the present embodiment. In the step with the same step number as in the flowchart of FIG. 11, similar operation is performed. The operation flow is different from that of the first embodiment in that, at the time of activation and when stopping generation of the EUV light 252, in a case of changing the gas supply amount of the buffer gas from the laser light path pipe 36 to the first flow rate which is smaller than the normal flow rate from the second flow rate which is the normal flow rate, the gas supply amount to be supplied from the gas supply unit 40a is set to the third flow rate which is the preparation flow rate being a larger gas flow rate than the fourth flow rate which is the normal flow rate. Here, in the description of the present embodiment, the gas supply unit 40a is deemed to be replaced with a second gas supply unit 40a.

The flowchart of FIG. 16 will be described in terms of differences from that of FIG. 11.

### (Step S114)

The present step is a step in which the processor 5 controls the flow rate of the buffer gas to be supplied from the laser light path pipe 36 and the flow rate of the buffer gas to be supplied from the gas supply unit 40a. The processor 5 sets the target flow rate of the buffer gas to be supplied from the first gas supply unit 40b to the first flow rate. Further, the processor 5 sets the target flow rate of the buffer gas to be supplied from the second gas supply unit 40a to the third flow rate, which is the preparation flow rate being a larger flow rate than the fourth flow rate, which is the normal flow rate.

### (Step S133)

The present step is a step in which the processor 5 changes the target flow rate of the buffer gas to be supplied from the laser light path pipe 36 and the target flow rate of the buffer gas to be supplied from the gas supply unit 40a. The processor 5 sets the target flow rate of the buffer gas to be supplied from the first gas supply unit 40b to the second flow rate, which is the normal flow rate. Further, the processor 5 sets the target flow rate of the buffer gas to be supplied from the second gas supply unit 40a to the fourth flow rate, which is the normal flow rate.

### (Step S161)

The present step is a step in which the processor 5 controls the flow rate of the buffer gas to be supplied from the laser light path pipe 36 and the flow rate of the buffer gas to be supplied from the gas supply unit 40a. The processor 5 sets the target flow rate of the buffer gas to be supplied from the first gas supply unit 40b to the first flow rate. Further, the processor 5 sets the target flow rate of the buffer gas to be supplied from the second gas supply unit 40a to the third flow rate, which is the preparation flow rate being a larger flow rate than the fourth flow rate, which is the normal flow rate.

### (Step S162)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S162. When the target supply unit 26 has reached the normal temperature and the normal pressure, processing proceeds to step S13.

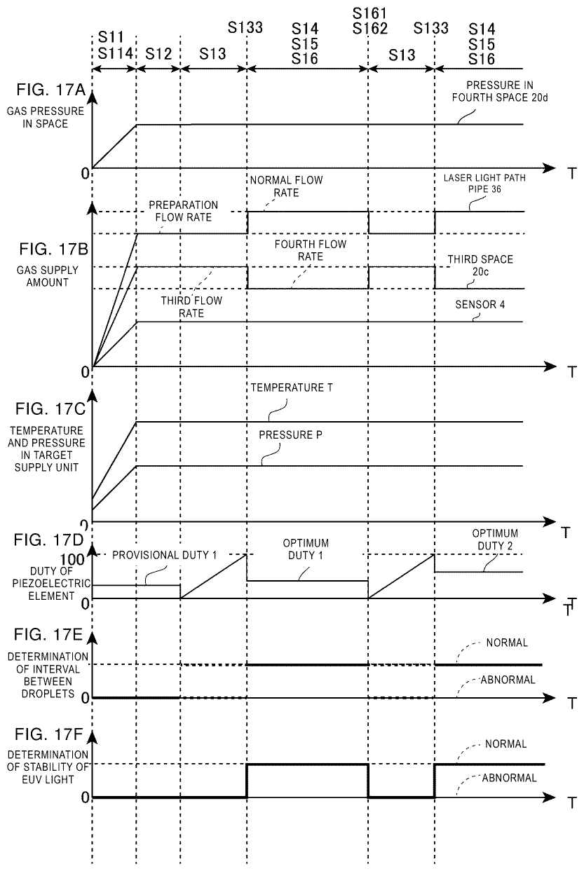

FIGS. 17A to 17F show timing charts showing state changes of respective configurations when steps S11 to S16 of FIG. 16 are executed. The horizontal axis in each chart represents the elapse of time, and the time is common. Dashed lines indicate points of change of a state. The number with S in the upper row is the number of the step executed between adjacent broken lines.

In FIG. 17A, transition of the pressure in the fourth space 20d is shown. As compared to FIG. 12A of the first embodiment, the pressure in the fourth space 20d is maintained at a substantially constant pressure during the entire period of steps S11 to S16. The processor 5 performs control so that the pressure in the fourth space 20d is maintained at the normal pressure during the entire period of steps S11 to S16. The pressure variation in the fourth space 20d is maintained within ±1.0 Pa with respect to the target pressure. The pressure variation in the fourth space 20d is preferably within ±0.5 Pa with respect to the target pressure.

As shown in FIG. 17B, in steps S14, S15, and S16, the flow rate of the buffer gas supplied from the second gas supply unit 40a is the fourth flow rate, which is the normal flow rate. On the other hand, in steps S12 and S13, the flow rate of the buffer gas supplied from the second gas supply unit 40a is the third flow rate, which is the preparation flow rate larger than the fourth flow rate, which is the normal flow rate. Therefore, as shown in FIG. 17A, the pressure in the fourth space 20d is maintained substantially constant.

Further, the temperature T and the pressure P of the target supply unit 26 shown in FIG. 17C are different from those in FIG. 12C of the first embodiment in that the variation thereof caused by the change in the flow rate of the buffer gas is negligibly small in any period.

### 5.3 Effect

According to the present embodiment, when the gas supply amount of the buffer gas from the laser light path pipe 36 is set to the first flow rate, which is smaller than the normal flow rate, from the second flow rate, which is the normal flow rate, the gas supply amount to be supplied from the gas supply unit 40a is set to the third flow rate, which is the preparation flow rate being a larger gas flow rate than the fourth flow rate, which is the normal flow rate. Therefore, even when the gas supply amount supplied from the laser light path pipe 36 varies, the pressure variation of the buffer gas can be suppressed, and the change in the heat transfer state from the heater 47 of the target supply unit 26 to the buffer gas can be suppressed. Further, since the variation in the temperature and the pressure of the target supply unit 26 can be set to be negligibly small, the extreme ultraviolet light generation apparatus 100 does not need to wait until the target supply unit 26 reaches the normal temperature and the normal pressure. Accordingly, the waiting time may be shortened.

### 5.4 First Modification

### 5.4.1 Configuration

Since the configuration of the extreme ultraviolet light generation apparatus 100 of a first modification of the second embodiment is similar to that of the first embodiment, description thereof will be omitted. The present modification is different from the second embodiment in that, at the time of activation and when stopping generation of the EUV light 252, in a case of changing the gas supply amount of the buffer gas from the laser light path pipe 36 to the first flow rate which is smaller than the normal flow rate from the second flow rate which is the normal flow rate, the gas supply amount to be supplied from the gas supply unit 40c is set to a fifth flow rate being a larger gas flow rate than a sixth flow rate which is the normal flow rate. Here, the buffer gas supply from the gas supply unit 40c is performed from at least one of the buffer gas supply ports 504b, 504c, 504d located in the vicinity of the sensors 4b, 4c, 4d. Here, in the description of the present modification, the gas supply unit 40c is deemed to be replaced with a second gas supply unit 40c.

### 5.4.2 Operation

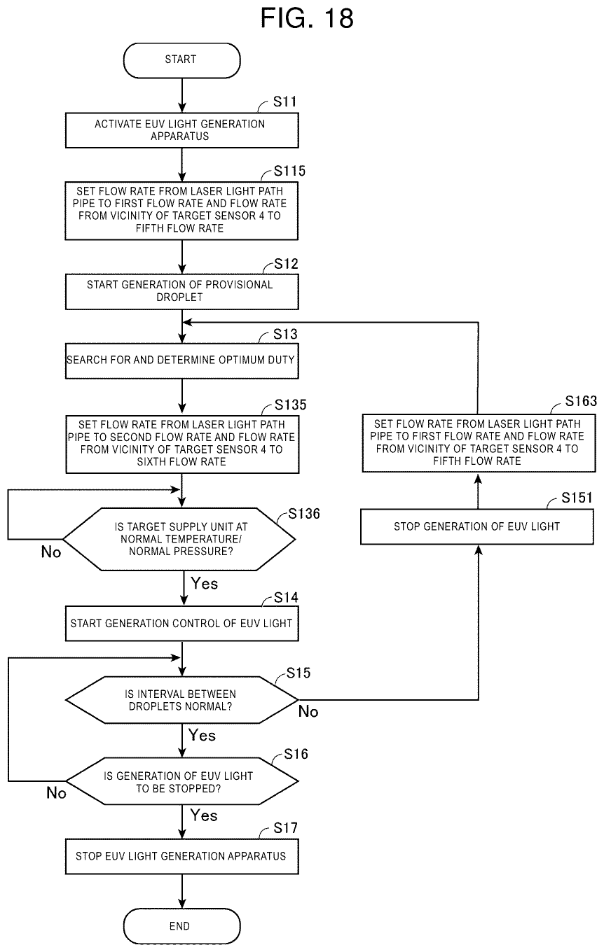

Next, operation of the first modification of the second embodiment will be described. FIG. 18 is a flowchart showing operation of the extreme ultraviolet light generation system 11 of the present modification. In the step with the same step number as in the flowchart of FIG. 11, similar operation is performed.

Hereinafter, the flowchart of FIG. 18 will be described in terms of differences from that of FIG. 11.

### (Step S115)

The present step is a step in which the processor 5 controls the flow rate of the buffer gas to be supplied from the laser light path pipe 36 and the flow rate of the buffer gas to be supplied from the gas supply unit 40c. The processor 5 sets the target flow rate of the buffer gas to be supplied from the first gas supply unit 40b to the first flow rate. Further, the processor 5 sets the gas supply amount to be supplied from the second gas supply unit 40c through at least one of the buffer gas supply ports 504b, 504c, 504d to the fifth flow rate, which is the preparation flow rate being a larger gas flow rate than the sixth flow rate, which is the normal flow rate.

### (Step S135)

The present step is a step in which the processor 5 changes the target flow rate of the buffer gas to be supplied from the laser light path pipe 36 and the target flow rate of the buffer gas to be supplied from the gas supply unit 40c. The processor 5 sets the target flow rate of the buffer gas to be supplied from the first gas supply unit 40b to the second flow rate, which is the normal flow rate. Further, the processor 5 sets the gas supply amount to be supplied from the second gas supply unit 40c through at least one of the buffer gas supply ports 504b, 504c, 504d to the sixth flow rate, which is the normal flow rate.

### (Step S136)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S136. When the target supply unit 26 has reached the normal temperature and the normal pressure, processing proceeds to step S14.

### (Step S163)

The present step is a step in which the processor 5 controls the flow rate of the buffer gas to be supplied from the laser light path pipe 36 and the flow rate of the buffer gas to be supplied from the gas supply unit 40c. The processor 5 sets the target flow rate of the buffer gas to be supplied from the first gas supply unit 40b to the first flow rate. Further, the processor 5 sets the gas supply amount to be supplied from the second gas supply unit 40c through at least one of the buffer gas supply ports 504b, 504c, 504d to the fifth flow rate. Then, processing returns to step S13.

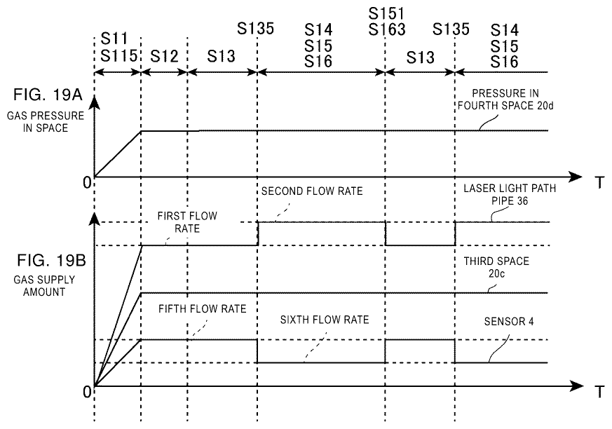

FIGS. 19A and 19B show timing charts showing state changes of respective configurations in steps S11 to S16 of FIG. 18. The horizontal axis in each chart represents the elapse of time, and the time is common. Dashed lines indicate points of change of a state. The number with S in the upper row is the number of the step executed between adjacent broken lines.

In FIG. 19A, transition of the pressure in the fourth space 20d is shown. The pressure in the fourth space 20d is maintained at a substantially constant pressure during the entire period of steps S12 to S16. The processor 5 performs control so that the pressure in the fourth space 20d is maintained at the normal pressure during the entire period of steps S11 to S16. The pressure variation in the fourth space 20d is maintained within ±1.0 Pa with respect to the target pressure. The pressure variation in the fourth space 20d is preferably within ±0.5 Pa with respect to the target pressure.

Here, as shown in FIG. 19B, in steps S14, S15, and S16, the flow rate of the buffer gas supplied from the second gas supply unit 40c is the sixth flow rate, which is the normal flow rate. On the other hand, in steps S12 and S13, the flow rate of the buffer gas supplied from the second gas supply unit 40c is the fifth flow rate, which is the preparation flow rate larger than the normal flow rate.

### 5.4.3 Effect

According to the present modification, when the gas supply amount of the buffer gas from the laser light path pipe 36 is changed to the first flow rate which is smaller than the normal flow rate from the second flow rate which is the normal flow rate, the processor 5 sets the gas supply amount to be supplied from the second gas supply unit 40c to the fifth flow rate which is the preparation flow rate being a larger gas flow rate than the sixth flow rate which is the normal flow rate. Therefore, even when the gas supply amount supplied from the laser light path pipe 36 varies, the pressure variation of the buffer gas can be suppressed, the change in the heat transfer state from the heater 47 of the target supply unit 26 to the buffer gas can be suppressed, and the variation in the temperature and the pressure of the target supply unit 26 can be made negligibly small. Therefore, the extreme ultraviolet light generation apparatus 100 does not need to wait until the target supply unit 26 reaches the normal temperature and the normal pressure. Accordingly, the waiting time may be shortened.

### 5.5 Second Modification

### 5.5.1 Configuration

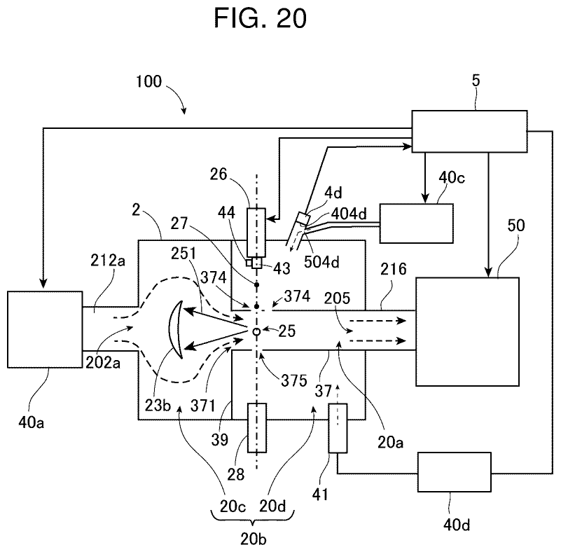

A second modification of the second embodiment will be described. As shown in FIG. 20, the configuration of the extreme ultraviolet light generation apparatus 100 of the second modification differs from the configuration of the first embodiment in that a dedicated gas supply unit 40d dedicated to supplying the buffer gas and a dedicated gas supply pipe 41 dedicated to supplying the buffer gas from the dedicated gas supply unit 40d to the chamber 2 are provided. Since other configurations are similar to those of the first embodiment, description thereof will be omitted.

### 5.5.2 Operation

Next, operation of the second modification of the second embodiment will be described. At the time of activation and when stopping generation of the EUV light 252, the gas supply amount of the buffer gas from the laser light path pipe 36 is set to the first flow rate, which is the preparation flow rate being a smaller gas flow rate than the normal flow rate, from the second flow rate, which is the normal flow rate. Further, the processor 5 sets the gas supply amount to be supplied from the dedicated gas supply unit 40d through the dedicated gas supply pipe 41 to a seventh flow rate which is the preparation flow rate being a larger gas flow rate than an eighth flow rate which is the normal flow rate. At this time, the processor 5 performs control so that the pressure in the fourth space 20d is maintained at the normal pressure during the entire period of steps S11 to S16. The pressure variation in the fourth space 20d is maintained within ±1.0 Pa with respect to the target pressure. The pressure variation in the fourth space 20d is preferably within ±0.5 Pa with respect to the target pressure.

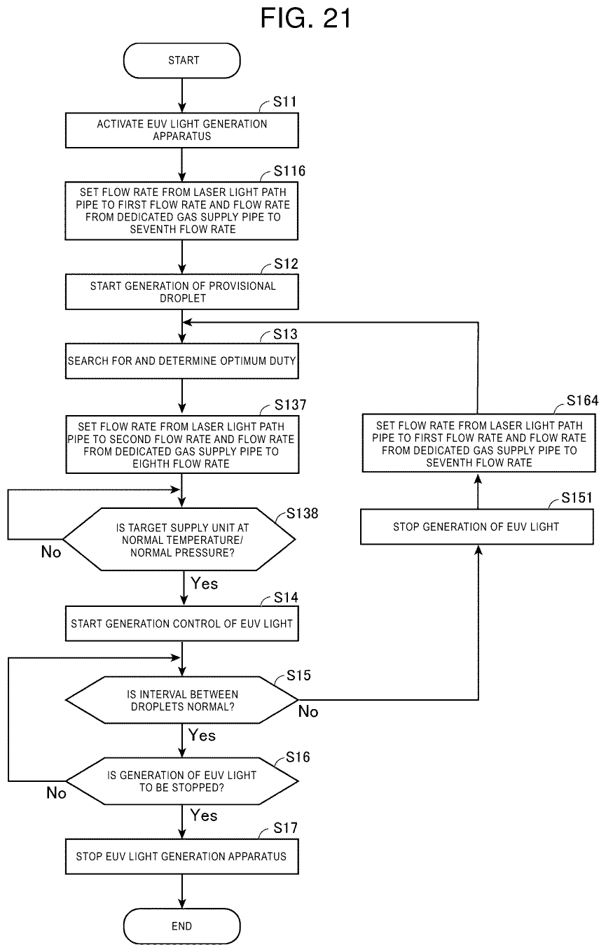

Hereinafter, the flowchart of FIG. 21 will be described in terms of differences from that of FIG. 18. In the step with the same step number as in the flowchart of FIG. 18, similar operation is performed.

### (Step S116)

The present step is a step in which the processor 5 controls the flow rate of the buffer gas to be supplied from the laser light path pipe 36 and the flow rate of the buffer gas to be supplied from the dedicated gas supply unit 40d. The processor 5 sets the target flow rate of the buffer gas to be supplied from the first gas supply unit 40b to the first flow rate. Further, the processor 5 sets the gas supply amount to be supplied from the dedicated gas supply unit 40d through the dedicated gas supply pipe 41 to the seventh flow rate which is the gas flow rate larger than the eighth flow rate, which is the normal flow rate.

### (Step S137)

The present step is a step in which the processor 5 changes the target flow rate of the buffer gas to be supplied from the laser light path pipe 36 and the target flow rate of the buffer gas to be supplied from the dedicated gas supply unit 40d. The processor 5 sets the target flow rate of the buffer gas to be supplied from the first gas supply unit 40b to the second flow rate, which is the normal flow rate. Further, the processor 5 sets the gas supply amount to be supplied from the dedicated gas supply unit 40d through the dedicated gas supply pipe 41 to the eighth flow rate, which is the normal flow rate.

### (Step S138)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S138. When the target supply unit 26 has reached the normal temperature and the normal pressure, processing proceeds to step S14.

### (Step S164)

The present step is a step in which the processor 5 controls the flow rate of the buffer gas to be supplied from the laser light path pipe 36 and the flow rate of the buffer gas to be supplied from the dedicated gas supply unit 40d. The processor 5 sets the target flow rate of the buffer gas to be supplied from the first gas supply unit 40b to the first flow rate. Further, the processor 5 sets the gas supply amount to be supplied from the dedicated gas supply unit 40d through the dedicated gas supply pipe 41 to the seventh flow rate. Next, processing returns to step S13.

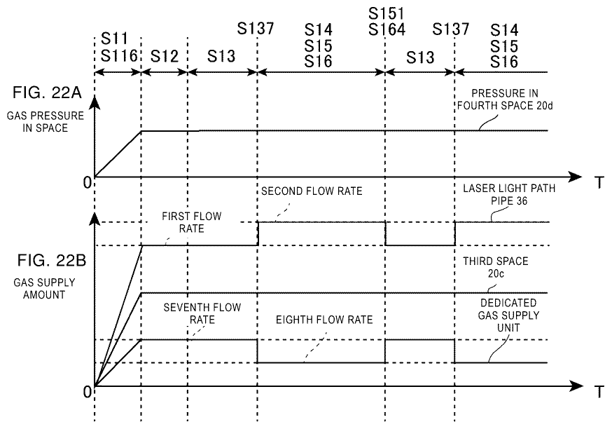

FIGS. 22A and 22B show timing charts showing state changes of respective configurations when steps S11 to S16 of FIG. 21 are executed. The horizontal axis in each chart represents the elapse of time, and the time is common. Dashed lines indicate points of change of a state. The number with S in the upper row is the number of the step executed between adjacent broken lines.

In FIG. 22A, transition of the pressure in the fourth space 20d is shown. The pressure in the fourth space 20d is maintained at a substantially constant pressure during the entire period of steps S11 to S16.

As shown in FIG. 22B, in steps S14, S15, and S16, the flow rate of the buffer gas supplied from the dedicated gas supply unit 40d is the eighth flow rate, which is the normal flow rate. On the other hand, in steps S12 and S13, the flow rate of the buffer gas supplied from the dedicated gas supply unit 40d is the seventh flow rate, which is the preparation flow rate larger than the normal flow rate.

### 5.5.3 Effect

According to the present modification, when the gas supply amount of the buffer gas from the laser light path pipe 36 is changed to the first flow rate which is smaller than the normal flow rate from the second flow rate which is the normal flow rate, the processor 5 sets the gas supply amount to be supplied from the dedicated gas supply unit 40d to the seventh flow rate which is the preparation flow rate being a larger gas flow rate than the eighth flow rate which is the normal flow rate. Therefore, even when the gas supply amount supplied from the laser light path pipe 36 varies, the pressure variation of the buffer gas can be suppressed, the change in the heat transfer state from the heater 47 of the target supply unit 26 to the buffer gas can be suppressed, and the variation in the temperature and the pressure of the target supply unit 26 can be made negligibly small. Therefore, the extreme ultraviolet light generation apparatus 100 does not need to wait until the target supply unit 26 reaches the normal temperature and the normal pressure. Accordingly, the waiting time may be shortened. Here, it is preferable that the direction of a supply port of the dedicated gas supply pipe 41 is set in a direction not toward the trajectory of the droplet 27. With such a configuration, since the buffer gas from the dedicated gas supply pipe 41 can be circulated at a position away from the trajectory of the droplet 27, the trajectory deviation of the droplet 27small is further suppressed.

### 6. Description of Extreme Ultraviolet Light Generation Apparatus of Third Embodiment

### 6.1 Configuration

Since the configuration of the extreme ultraviolet light generation apparatus 100 of the present embodiment is similar to that of the first embodiment and that of the second embodiment, description thereof will be omitted. The present embodiment differs from the second embodiment in that, at the time of activation and when stopping generation of the EUV light 252, in a case of changing the gas supply amount of the buffer gas from the laser light path pipe 36 to the first flow rate which is the preparation flow rate smaller than the normal flow rate from the second flow rate which is the normal flow rate, an exhaust amount from the gas exhaust unit 50 is set to a preparation exhaust amount smaller than a normal exhaust amount so that the pressure variation in the fourth space 20d is small. At this time, the processor 5 performs control so that the pressure in the fourth space 20d is maintained at the normal pressure during the entire period of steps S11 to S16. The pressure variation in the fourth space 20d is maintained within ±1.0 Pa with respect to the target pressure. The pressure variation in the fourth space 20d is preferably within ±0.5 Pa with respect to the target pressure.

### 6.2 Operation

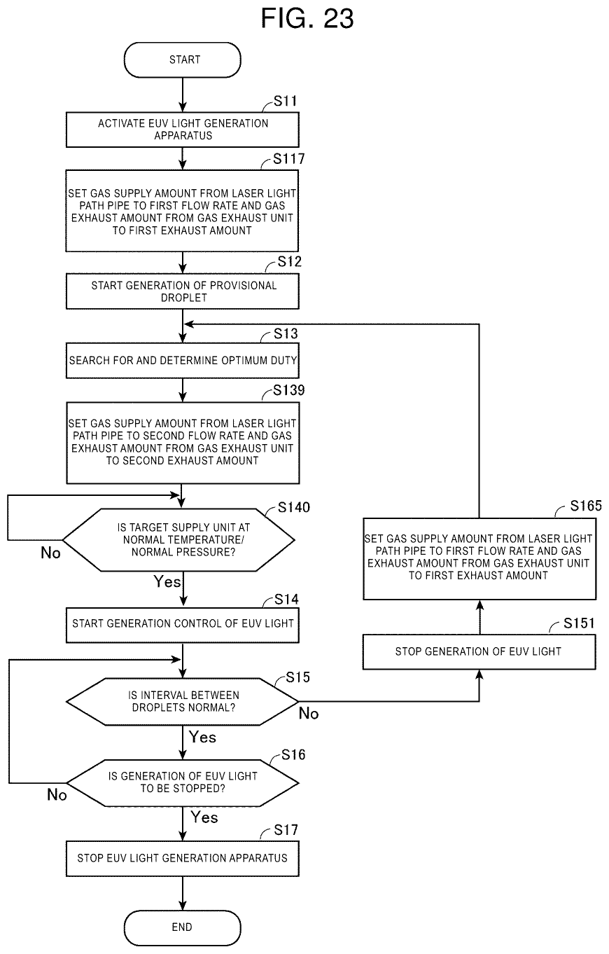

Next, operation of the third embodiment will be described. FIG. 23 is a flowchart showing operation of the extreme ultraviolet light generation system 11 of the present embodiment. In the step with the same step number as in the flowchart of FIG. 11, similar operation is performed. The operation flow is different from that of the second embodiment in that, at the time of activation and when stopping generation of the EUV light 252, in a case of changing the gas supply amount of the buffer gas from the laser light path pipe 36 to the first flow rate which is smaller than the normal flow rate from the second flow rate which is the normal flow rate, the gas exhaust amount to be exhausted from the gas exhaust unit 50 is set to a first exhaust amount which is the preparation exhaust amount smaller than the second exhaust amount which is the normal exhaust amount.

The flowchart of FIG. 23 will be described in terms of differences from that of FIG. 11.

### (Step S117)

The present step is a step in which the processor 5 controls the flow rate of the buffer gas to be supplied from the laser light path pipe 36 and the exhaust amount of the buffer gas to be exhausted from the gas exhaust unit 50. The processor 5 sets the buffer gas to be supplied from the first gas supply unit 40b to the first flow rate. Further, the processor 5 sets the gas exhaust amount to be exhausted from the gas exhaust unit 50 to the first exhaust amount, which is the preparation exhaust amount smaller than the second exhaust amount, which is the normal exhaust amount.

### (Step S139)

The present step is a step in which the processor 5 changes the target flow rate of the buffer gas to be supplied from the laser light path pipe 36 and the target exhaust amount of the buffer gas to be exhausted from the gas exhaust unit 50. The processor 5 sets the buffer gas to be supplied from the first gas supply unit 40b to the second flow rate, which is the normal flow rate. Further, the processor 5 sets the gas exhaust amount to be exhausted from the gas exhaust unit 50 to the second exhaust amount, which is the normal exhaust amount.

### (Step S140)

The present step is a step in which the processor 5 causes waiting until the target supply unit 26 reaches the normal temperature and the normal pressure. The processor 5 causes the extreme ultraviolet light generation apparatus 100 to wait until the target supply unit 26 reaches the normal temperature and the normal pressure. When the target supply unit 26 has not reached the normal temperature and the normal pressure, the processor 5 continues S140. When the target supply unit 26 has reached the normal temperature and the normal pressure, processing proceeds to step S14.

### (Step S165)

The present step is a step in which the processor 5 controls the flow rate of the buffer gas to be supplied from the laser light path pipe 36 and the exhaust amount of the buffer gas to be exhausted from the gas exhaust unit 50. The processor 5 sets the buffer gas to be supplied from the first gas supply unit 40b to the first flow rate. Further, the processor 5 sets the gas exhaust amount to be exhausted from the gas exhaust unit 50 to the first exhaust amount, which is the preparation exhaust amount smaller than the second exhaust amount, which is the normal exhaust amount. Then, processing returns to step S13.

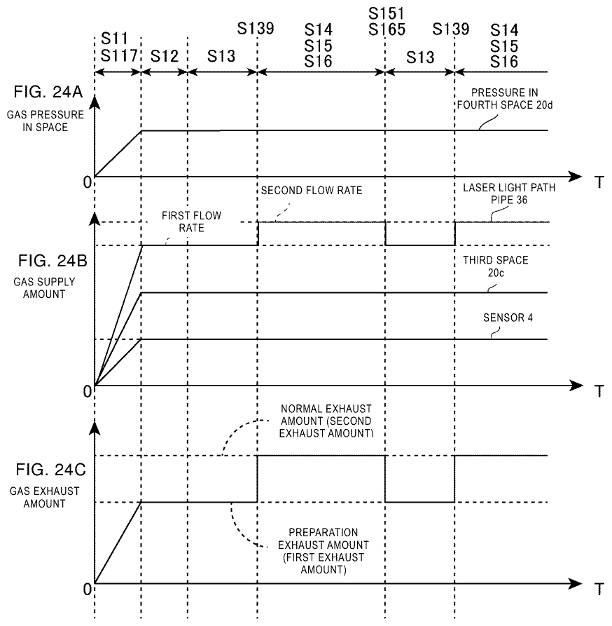

FIGS. 24A to 24C show timing charts showing state changes of respective configurations when steps S11 to S16 of FIG. 23 are executed. The horizontal axis in each chart represents the elapse of time, and the time is common. Dashed lines indicate points of change of a state. The number with S in the upper row is the number of the step executed between adjacent broken lines.

In FIG. 24A, transition of the pressure in the fourth space 20d is shown. The pressure in the fourth space 20d is maintained at a substantially constant pressure during the entire period of steps S12 to S16. The pressure variation in the fourth space 20d is maintained within ±1.0 Pa with respect to the target pressure. The pressure variation in the fourth space 20d is preferably within #0.5 Pa with respect to the target pressure.

As shown in FIG. 24C, in steps S14, S15, and S16, the flow rate of the gas exhausted from the gas exhaust unit 50 is the second exhaust amount, which is the normal exhaust amount. On the other hand, in steps S12 and S13, the exhaust amount of the gas exhausted from the gas exhaust unit 50 is the first exhaust amount, which is the preparation exhaust amount smaller than the normal exhaust amount.

### 6.3 Effect

According to the present embodiment, when the gas supply amount of the buffer gas from the laser light path pipe 36 is changed to the first flow rate which is smaller than the normal flow rate from the second flow rate, which is the normal flow rate, the processor 5 sets the exhaust amount of the gas to be exhausted from the gas exhaust unit 50 to the first exhaust amount which is the preparation exhaust amount rate smaller than the second exhaust amount which is the normal exhaust amount. Therefore, even when the gas supply amount supplied from the laser light path pipe 36 varies, the pressure variation of the buffer gas can be suppressed, the change in the heat transfer state from the heater 47 of the target supply unit 26 to the buffer gas can be suppressed, and the variation in the temperature and the pressure of the target supply unit 26 can be made negligibly small. Therefore, the extreme ultraviolet light generation apparatus 100 does not need to wait until the target supply unit 26 reaches the normal temperature and the normal pressure. Accordingly, the waiting time may be shortened.

The processor 5 and other processors such as a laser control processor for controlling the laser device 3 and an exposure control processor for controlling the exposure apparatus 200 of the present disclosure may be configured physically as hardware to execute the various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU. Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An extreme ultraviolet light generation apparatus comprising:
a chamber in which a target substance supplied to a plasma generation region at an internal space thereof is irradiated with laser light to generate extreme ultraviolet light;
a laser device configured to generate the laser light;
a target supply unit configured to supply a droplet of the target substance toward the plasma generation region;
a target collection unit arranged on a trajectory of the output target substance and configured to collect the target substance which has not been irradiated with the laser light;
a first gas supply unit configured to supply a buffer gas into the chamber; and
a processor,
the processor being configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.

2. The extreme ultraviolet light generation apparatus according to claim 1,
wherein the first period is a time of activation of the extreme ultraviolet generation apparatus.

3. The extreme ultraviolet light generation apparatus according to claim 1,
wherein the processor further preforms determination of stability of the extreme ultraviolet light, and
the first period is a period in which generation of the extreme ultraviolet light is stopped when the processor determines that the stability of the extreme ultraviolet light is abnormal.

4. The extreme ultraviolet light generation apparatus according to claim 1,
wherein the target supply unit includes a nozzle from which the droplet of the target substance is output, and a piezoelectric element that vibrates the nozzle, and
the first period is a period including at least a part of a search period for searching for and determining an optimum duty of an electric signal to be applied to the piezoelectric element.

5. The extreme ultraviolet light generation apparatus according to claim 4,
wherein the first period is a period further including a period until an electric signal having the optimum duty determined in the search period is applied to the nozzle.

6. The extreme ultraviolet light generation apparatus according to claim 1,
wherein the buffer gas contains hydrogen gas.

7. The extreme ultraviolet light generation apparatus according to claim 1,
further comprising an optical path pipe surrounding an optical path of the laser light in the chamber,
wherein the optical path pipe is provided with a first opening opening toward the plasma generation region, and the buffer gas is supplied toward the plasma generation region through the first opening, and the laser light is radiated toward the plasma generation region through the first opening.

8. The extreme ultraviolet light generation apparatus according to claim 7,
wherein the optical path pipe further includes a second opening for guiding the buffer gas into the optical path pipe.

9. The extreme ultraviolet light generation apparatus according to claim 1,
further comprising a gas exhaust unit configured to exhaust a gas at the internal space.

10. The extreme ultraviolet light generation apparatus according to claim 9,
wherein the processor further controls the gas exhaust unit to decrease a gas exhaust amount from the gas exhaust unit as compared to a case in which the flow rate of the buffer gas is the second flow rate so that a pressure in the plasma generation region becomes within a predetermined range from a predetermined target pressure in at least a part of a period in which the flow rate of the buffer gas is the first flow rate.

11. The extreme ultraviolet light generation apparatus according to claim 10,
wherein the predetermined range is within ±1.0 Pa with respect to the target pressure.

12. The extreme ultraviolet light generation apparatus according to claim 9,
further comprising a cylindrical body that guides the gas in the chamber to the gas exhaust unit,
wherein the plasma generation region is located in a through hole of the cylindrical body.

13. The extreme ultraviolet light generation apparatus according to claim 12,
wherein the cylindrical body includes a first cylindrical body opening at an end part on a side opposite to the gas exhaust unit side, and a second cylindrical body opening at an end part on the gas exhaust unit side.

14. The extreme ultraviolet light generation apparatus according to claim 12,
further comprising a partition wall, in the chamber, that partitions a first space accommodating an optical path pipe provided on the cylindrical body and a side surface of the cylindrical body and surrounding an optical path of the laser light, and a second space accommodating an extreme ultraviolet light concentrating mirror that concentrates the extreme ultraviolet light.

15. The extreme ultraviolet light generation apparatus according to claim 1,
further comprising a second gas supply unit configured to supply the buffer gas into the chamber,
wherein the processor further controls the second gas supply unit to increase a flow rate of the buffer gas to be supplied from the second gas supply unit in the first period as compared to a flow rate in the second period so that a pressure in the plasma generation region becomes within a predetermined range from a target pressure.

16. The extreme ultraviolet light generation apparatus according to claim 15,
wherein the predetermined range is within ±1.0 Pa with respect to the target pressure.

17. The extreme ultraviolet light generation apparatus according to claim 15,
wherein a supply port through which the buffer gas from the second gas supply unit is supplied is provided in a vicinity of a detection window for a sensor for detecting the droplet.

18. The extreme ultraviolet light generation apparatus according to claim 15,
wherein a supply port through which the buffer gas from the second gas supply unit is supplied is not open toward the plasma generation region.

19. An electronic device manufacturing method, comprising:
outputting extreme ultraviolet light generated using an extreme ultraviolet light generation apparatus to an exposure apparatus; and
exposing a photosensitive substrate to the extreme ultraviolet light in the exposure apparatus to manufacture an electronic device,
the extreme ultraviolet light generation apparatus including:
a chamber in which a target substance supplied to a plasma generation region at an internal space thereof is irradiated with laser light to generate the extreme ultraviolet light;
a laser device configured to generate the laser light;
a target supply unit configured to output a droplet of the target substance toward the plasma generation region;
a target collection unit arranged on a trajectory of the output target substance and configured to collect the target substance which has not been irradiated with the laser light;
a first gas supply unit configured to supply a buffer gas into the chamber; and
a processor,
the processor being configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.

20. An electronic device manufacturing method, comprising:
inspecting a defect of a mask by irradiating the mask with extreme ultraviolet light generated using an extreme ultraviolet light generation apparatus;
selecting a mask using a result of the inspection; and
exposing and transferring a pattern formed on the selected mask onto a photosensitive substrate,
the extreme ultraviolet light generation apparatus including:
a chamber in which a target substance supplied to a plasma generation region at an internal space thereof is irradiated with laser light to generate the extreme ultraviolet light;
a laser device configured to generate the laser light;
a target supply unit configured to output a droplet of the target substance toward the plasma generation region;
a target collection unit arranged on a trajectory of the output target substance and configured to collect the target substance which has not been irradiated with the laser light;
a first gas supply unit configured to supply a buffer gas into the chamber; and
a processor,
the processor being configured to control the first gas supply unit so that, in a period in which the target supply unit outputs the droplet, a first flow rate which is a flow rate of the buffer gas to be supplied from the first gas supply unit in at least a part of a first period being a period in which the droplet is not irradiated with the laser light is smaller than a second flow rate which is a flow rate of the buffer gas to be supplied from the first gas supply unit in a second period being a period in which the droplet is irradiated with the laser light.
